(19) United States
(12) Patent Application Publication
(10) Pub. No.: US 2015/0187652 A1
(43) Pub. Date: Jul. 2, 2015

(54) METHOD FOR PRODUCING A COMPOSITE WAFER AND A METHOD FOR PRODUCING A SEMICONDUCTOR CRYSTAL LAYER FORMING WAFER

(71) Applicants: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP); HITACHI KOKUSAI ELECTRIC INC., Tokyo (JP)

(72) Inventors: Taketsugu YAMAMOTO, Tsukuba-shi (JP); Takeshi AOKI, Niihama-shi (JP); Tatsuro MAEDA, Tsukuba-shi (JP); Eiko MIEDA, Tsukuba-shi (JP); Toshiyuki KIKUCHI, Toyama-shi (JP); Arito OGAWA, Toyama-shi (JP)

(73) Assignees: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP); HITACHI KOKUSAI ELECTRIC INC., Tokyo (JP)

(21) Appl. No.: 14/607,254

(22) Filed: Jan. 28, 2015

Related U.S. Application Data
(63) Continuation-in-part of application No. PCT/JP2013/004618, filed on Jul. 30, 2013.

(30) Foreign Application Priority Data
Jul. 30, 2012 (JP) 2012-169016
Dec. 7, 2012 (JP) 2012-267877

(51) Int. Cl. H01L 21/8258; H01L 21/78; H01L 21/306; H01L 21/02

(52) U.S. Cl. CPC H01L 21/8258; H01L 21/02598; H01L 21/7813; H01L 21/30604

(57) ABSTRACT

A method for producing a composite wafer by using a forming wafer having a monocrystal layer, the method comprising:
(a) forming, on the monocrystal layer of the forming wafer, a sacrificial layer and a semiconductor crystal layer sequentially;
(b) causing a first front surface that is the front surface of a layer formed on the forming wafer to face a second front surface that is the front surface of the transfer target wafer or of a layer formed on the transfer target wafer and is to contact the first front surface, and bonding the forming wafer and the transfer target wafer; and
(c) etching the sacrificial layer, and separating the forming wafer from the transfer target wafer in a state that the semiconductor crystal layer is left on the transfer target wafer, wherein
the (a) to the (c) are repeated by using the forming wafer separated in the (c).

The contents of the following patent applications are incorporated herein by reference:
NO. 2012-169016 filed in Japan on Jul. 30, 2012,
NO. 2012-267877 filed in Japan on Dec. 7, 2012, and
NO. PCT/JP2013/004618 filed on Jul. 30, 2013.

### BACKGROUND

1. Technical Field

The present invention relates to a method for producing a composite wafer, and a method for producing a semiconductor crystal layer forming wafer.

2. Related Art

Group III-V compound semiconductors such as GaAs, InGaAs and InP have high electron mobility. Group IV semiconductors such as Ge and SiGe have high hole mobility. Therefore, a highly advanced CMOSFET (complementary metal-oxide-semiconductor field effect transistor) can be realized if the Group III-V compound semiconductors are used to form an N-channel MOSFET (metal-oxide-semiconductor field effect transistor) (hereinafter, may be simply referred to as nMOSFET) and the Group IV semiconductors are used to form a P-channel MOSFET (hereinafter, may be simply referred to as “pMOSFET”). Non-Patent Document 1 discloses a CMOSFET structure in which an N-channel MOSFET having a channel made of a Group III-V compound semiconductor and a P-channel MOSFET having a channel made of Ge are formed on a single wafer.

To form heterogeneous materials of a Group III-V compound semiconductor crystal layer and a Group IV semiconductor crystal layer on a single wafer (for example, a silicon wafer), a technique is known to transfer onto a transfer target wafer a semiconductor crystal layer that has been formed on a semiconductor crystal growth wafer. For example, Non-Patent Document 2 discloses a technique according to which an AlAs layer is formed as a sacrificial layer on a GaAs wafer and a Ge layer is formed on the sacrificial layer (AlAs layer) and transferred onto a silicon wafer.
[Non-Patent Document 1] S. Takagi, et al., SSE, vol. 51, pp. 526-536, 2007.
[Non-Patent Document 2] Y. Bai and E. A. Fitzgerald, ECS Transactions, 33 (6) 927-932 (2010)

### SUMMARY

To form on a single wafer an N-channel MISFET (metal-insulator-semiconductor field effect transistor) (hereinafter, may be simply referred to as “nMISFET”) having a channel made of a Group III-V compound semiconductor and a P-channel MISFET (hereinafter, may be simply referred to as “pMISFET”) having a channel made of a Group IV semiconductor, it is necessary to develop a technique of forming the Group III-V compound semiconductor crystal layer for the n-MISFET and the Group IV semiconductor crystal layer for the p-MISFET on the single wafer. Furthermore, taking into consideration that the nMISFET and the pMISFET are produced as a LSI (large scale integration), a semiconductor crystal layer for an nMISFET or a pMISFET is preferably formed on a silicon wafer that allows utilization of existing production devices and existing steps. By using the technique of Non-Patent Document 2, a Group III-V compound semiconductor crystal layer and a Group IV semiconductor crystal layer can be formed on a single wafer, and these semiconductor crystal layers can be formed on a silicon wafer that is advantageous in terms of production.

Expensive materials such as a compound semiconductor monocrystal wafer and the like are used for a semiconductor crystal layer forming wafer for forming a semiconductor crystal layer to be transferred. Use of a sacrificial layer described in Non-Patent Document 2 allows reuse of a semiconductor crystal layer forming wafer, and certain effects can be expected in reduction of the production cost. However, further cost reduction is desired. Also, because it is difficult to obtain a compound semiconductor crystal wafer with a large diameter as a semiconductor monocrystal layer forming wafer, it is not possible to try to reduce production cost by enlarging the diameter of a wafer size. Furthermore, if a semiconductor crystal layer can be formed on a semiconductor crystal layer forming wafer by taking into consideration the planar shape (pattern) obtained after the semiconductor crystal layer is transferred onto a transfer target wafer, it becomes possible to simplify processes, and the possibility of reducing the production cost becomes higher.

An object of the present invention is to provide a semiconductor crystal layer forming wafer with a large diameter that can be used multiple times. Also, another object is to provide a method for producing a composite wafer in which the semiconductor crystal layer forming wafer with a large diameter is used to form a semiconductor crystal layer. Also, another object is to provide a semiconductor crystal layer forming wafer that makes it possible to fabricate a pattern of a semiconductor crystal layer to be used for a transfer target wafer in advance during a step to form a semiconductor crystal layer. Furthermore, another object is to provide a semiconductor crystal layer forming wafer that can be used stably even multiple times.

In order to solve the above-described problems, a first aspect of the present invention provides a method for producing a composite wafer that has a semiconductor crystal layer on a transfer target wafer by using a semiconductor crystal layer forming wafer, the semiconductor crystal layer forming wafer having a support wafer and a monocrystal layer supported, directly or via an intermediate layer, on the front surface or the back surface of the support wafer, the method comprising:

(a) forming, on the monocrystal layer of the semiconductor crystal layer forming wafer, a sacrificial layer and the semiconductor crystal layer in the order of the monocrystal layer, the sacrificial layer, and the semiconductor crystal layer;

(b) causing a first front surface that is the front surface of a layer formed on the semiconductor crystal layer forming wafer to face a second front surface that is the front surface of the transfer target wafer or of a layer formed on the transfer target wafer and is to contact the first front surface, and bonding the semiconductor crystal layer forming wafer and the transfer target wafer; and
(c) etching the sacrificial layer, and separating the semiconductor crystal layer forming wafer from the transfer target wafer in a state that the semiconductor crystal layer is left on the transfer target wafer, wherein

the (a) to the (c) are repeated by using the semiconductor crystal layer forming wafer separated in the (c).

The method may further comprise, before the (a), smoothing the front surface of the monocrystal layer of the semiconductor crystal layer forming wafer. The method may further comprise, after the (a) and before the (b), etching the semiconductor crystal layer so as to expose a part of the sacrificial layer, and dividing the semiconductor crystal layer into a plurality of divided pieces. The method may further comprise, after the (a) and before the (b), activating one or more front surfaces selected from the first front surface and the second front surface. The method may further comprise, after the (a) and before the (b), forming an insulating layer on the semiconductor crystal layer. The method may further comprise, before the (b), forming an insulating layer on the front surface of the transfer target wafer or of a layer formed on the transfer target wafer, the front surface being positioned on the semiconductor crystal layer forming wafer side. The transfer target wafer may have a circular shape with a diameter of 200 mm or has any planar shape having an area larger than the circular shape. The method may further comprise:

before the (b), forming an adhesive layer on the front surface of the transfer target wafer or of a layer formed on the transfer target wafer, the front surface being positioned on the semiconductor crystal layer forming wafer side;

after the (c), causing a third front surface that is the front surface of the semiconductor crystal layer on the transfer target wafer or the front surface of a layer formed on the semiconductor crystal layer to face a fourth front surface that is the front surface of a second transfer target wafer or of a layer formed on the second transfer target wafer, and is to contact the third front surface, and bonding the transfer target wafer and the second transfer target wafer; and

removing the adhesive layer of the transfer target wafer, and separating the transfer target wafer and the second transfer target wafer in a state that the semiconductor crystal layer is left on the second transfer target wafer.

A second aspect of the present invention provides a method for producing a semiconductor crystal layer forming wafer to be used in the method for producing a composite wafer according to claim 1, the method for producing a semiconductor crystal layer forming wafer comprising:

smoothing one or more front surfaces selected from a fifth front surface of the support wafer that is to contact the monocrystal layer and a sixth front surface of the monocrystal layer that is to contact the support wafer;

activating one or more front surfaces selected from the fifth front surface and the sixth front surface; and

causing the fifth front surface to face the sixth front surface, and bonding the support wafer and the monocrystal layer to form the monocrystal layer on the support wafer.

A third aspect of the present invention provides a method for producing a semiconductor crystal layer forming wafer to be used in the method for producing a composite wafer according to claim 1, the method for producing a semiconductor crystal layer forming wafer comprising:

forming a heat resistant intermediate layer on one or more front surfaces selected from the front surface positioned on the monocrystal layer side of the support wafer and the front surface positioned on the support wafer side of the monocrystal layer;

causing a seventh front surface that is the front surface of the support wafer or of the intermediate layer formed on the support wafer to face an eighth surface that is the front surface of the monocrystal layer or of the intermediate layer formed on the monocrystal layer, and is to contact the seventh front surface, and bonding the support wafer and the monocrystal layer to form the monocrystal layer on the support wafer.

In the third aspect, the method may further comprise, after forming the intermediate layer and before the bonding, activating one or more front surfaces selected from the seventh front surface and the eighth surface. The method may further comprise, after forming the intermediate layer, and before the activation, smoothing one or more front surfaces selected from the seventh front surface and the eighth surface.

In the second and third aspects, examples of the smoothing include a step of polishing a surface by CMP. Also, examples of the activating include a step of irradiating a surface with ion beam. In the bonding, the support wafer and the monocrystal layer may be heated to 100 to 200° C. The support wafer may have a circular shape with a diameter of 200 mm or has any planar shape having an area larger than the circular shape. When the planar shape of the monocrystal layer bonded to the support wafer has a corner, the method may further comprise after bonding the support wafer and the monocrystal layer, performing processing to round the corner of the monocrystal layer.

A fourth aspect of the present invention provides a method for producing a semiconductor crystal layer forming wafer to be used in the above-described method for producing a composite wafer, the method for producing a semiconductor crystal layer forming wafer comprising:

forming a monocrystal growth layer on the support wafer by using epitaxial growth; and

forming the monocrystal layer on the support wafer by patterning the monocrystal growth layer.

In the second to fourth aspects, the method may further comprise, before forming the monocrystal layer on the support wafer, forming a concave portion on the support wafer, wherein

in forming the monocrystal layer, the monocrystal layer is formed at the concave portion. When the monocrystal layer is formed in the concave portion, the method may further comprise polishing the monocrystal layer or the support wafer such that the front surface of the monocrystal layer formed at the concave portion becomes substantially flush with the front surface of the support wafer.

In the second to fourth aspects, when the monocrystal layer is formed on the support wafer, the method may further comprise, before forming the monocrystal layer on the support wafer, performing surface processing on a region of the support wafer where the monocrystal layer is formed or is not formed, wherein

in forming the monocrystal layer, the monocrystal layer is formed in the region on which the surface processing has been performed or has not been performed, the monocrystal layer being formed by being caused to self-align with the region. In this case, the method may further comprise, after forming a monocrystal layer on the support wafer, making the monocrystal layer thin. When a plurality of the monocrystal layers is formed on the single support wafer, in making the monocrystal layers thin, the monocrystal layers may be made thin by simultaneously polishing the front surfaces of all the monocrystal layers on the support wafer.

In the second to fourth aspects, when a plurality of crystal layers is formed within a surface of the single support wafer, and a groove is constituted with two adjacent ones of the monocrystal layers, and the support wafer, the method may further comprise forming a filling layer to fill the groove. In this case, the method may further comprise polishing the monocrystal layer or the filling layer such that the front surface of the monocrystal layer becomes substantially flush with the front surface of the filling layer.

The method may further comprise forming a growth inhibition layer to inhibit growth of the semiconductor crystal layer on one or more surfaces that are selected from: the side surface of the monocrystal layer formed on the support wafer; the front surface of a layer formed on the side surface; the front surface of the support wafer in a non-formation region where the monocrystal layer is not formed; and the front surface of a layer formed on the support wafer in the non-formation region. The method may further comprise, after forming the monocrystal layer on the support wafer, forming a buffer layer on the monocrystal layer. The method may further comprise, after forming the monocrystal layer on the support wafer, forming a protection layer to cover the monocrystal layer over the entire surface of the support wafer on which the monocrystal layer is formed, and removing a part of the protection layer such that the front surface of the monocrystal layer or a layer formed on the monocrystal layer is exposed.

The summary clause does not necessarily describe all necessary features of the embodiments of the present invention. The present invention may also be a sub-combination of the features described above.

### BRIEF DESCRIPTION OF THE DRAWINGS

FIG. 1 is a plan view of a semiconductor crystal layer forming wafer 100 to be used in a method for producing a composite wafer according to a first embodiment.

FIG. 2 is a cross-sectional view of the semiconductor crystal layer forming wafer 100 to be used in the method for producing a composite wafer according to the first embodiment.

FIG. 3 is a cross-sectional view illustrating, in the order of steps, the method for producing a composite wafer according to the first embodiment.

FIG. 4 is a cross-sectional view illustrating, in the order of steps, the method for producing a composite wafer according to the first embodiment.

FIG. 5 is a cross-sectional view illustrating, in the order of steps, the method for producing a composite wafer according to the first embodiment.

FIG. 6 is a cross-sectional view illustrating, in the order of steps, the method for producing a composite wafer according to the first embodiment.

FIG. 7 is a plan view illustrating, in the order of steps, the method for producing a composite wafer according to the first embodiment.

FIG. 8A is a plan view illustrating an example of the planar shape of divided pieces 108.

FIG. 8B is a plan view illustrating an example of the planar shape of the divided pieces 108.

FIG. 8C is a plan view illustrating an example of the planar shape of the divided pieces 108.

FIG. 9A is a plan view illustrating an example of the planar shape of the divided pieces 108.

FIG. 9B is a plan view illustrating an example of the planar shape of the divided pieces 108.

FIG. 9C is a plan view illustrating an example of the planar shape of the divided pieces 108.

FIG. 9D is a plan view illustrating an example of the planar shape of the divided pieces 108.

FIG. 9E is a plan view illustrating an example of the planar shape of the divided pieces 108.

FIG. 10 is a cross-sectional view illustrating, in the order of steps, the method for producing a composite wafer according to the first embodiment.

FIG. 11 is a cross-sectional view illustrating, in the order of steps, the method for producing a composite wafer according to the first embodiment.

FIG. 12 is a cross-sectional view illustrating, in the order of steps, the method for producing a composite wafer according to the first embodiment.

FIG. 13 is a cross-sectional view illustrating, in the order of steps, the method for producing a composite wafer according to the first embodiment.

FIG. 14 is a plan view of a composite wafer 200 produced in the method according to the first embodiment.

FIG. 15 is a cross-sectional view illustrating, in the order of steps, a method for producing a composite wafer according to a second embodiment.

FIG. 16 is a cross-sectional view illustrating, in the order of steps, the method for producing a composite wafer according to the second embodiment.

FIG. 17 is a cross-sectional view illustrating, in the order of steps, the method for producing a composite wafer according to the second embodiment.

FIG. 18 is a cross-sectional view illustrating, in the order of steps, a method for producing a semiconductor crystal layer forming wafer according to a third embodiment.

FIG. 19 is a cross-sectional view illustrating, in the order of steps, the method for producing a semiconductor crystal layer forming wafer according to the third embodiment.

FIG. 20 is a cross-sectional view illustrating, in the order of steps, the method for producing a semiconductor crystal layer forming wafer according to the third embodiment.

FIG. 21 is a cross-sectional view illustrating, in the order of steps, the method for producing a semiconductor crystal layer forming wafer according to the third embodiment.

FIG. 22 is a cross-sectional view of the semiconductor crystal layer forming wafer 100 produced in the method according to the third embodiment.

FIG. 23 is a cross-sectional view illustrating, in the order of steps, a method for producing a semiconductor crystal layer forming wafer according to a fourth embodiment.

FIG. 24 is a cross-sectional view illustrating, in the order of steps, a method for producing a semiconductor crystal layer forming wafer according to the fourth embodiment.

FIG. 25 is a cross-sectional view of a semiconductor crystal layer forming wafer 300 produced in the method according to the fourth embodiment.

FIG. 26 is a plan view of a semiconductor crystal layer forming wafer 400.

FIG. 27 is a cross-sectional view illustrating, in the order of steps, a method for producing a semiconductor crystal layer forming wafer according to a fifth embodiment.

FIG. 28 is a cross-sectional view illustrating, in the order of steps, the method for producing a semiconductor crystal layer forming wafer according to the fifth embodiment.

FIG. 29 is a cross-sectional view illustrating, in the order of steps, the method for producing a semiconductor crystal layer forming wafer according to the fifth embodiment.

FIG. 30 is a cross-sectional view illustrating, in the order of steps, the method for producing a semiconductor crystal layer forming wafer according to the fifth embodiment.

FIG. 31 is a cross-sectional view of a semiconductor crystal layer forming wafer 500 produced in the method according to the fifth embodiment.

FIG. 32 is a cross-sectional view illustrating, in the order of steps, a method for producing a semiconductor crystal layer forming wafer according to a sixth embodiment.

FIG. 33 is a cross-sectional view illustrating, in the order of steps, a method for producing a semiconductor crystal layer forming wafer according to a sixth embodiment.

FIG. 34 is a cross-sectional view illustrating, in the order of steps, the method for producing a semiconductor crystal layer forming wafer according to the sixth embodiment.

FIG. 35 is a cross-sectional view illustrating, in the order of steps, the method for producing a semiconductor crystal layer forming wafer according to the sixth embodiment.

FIG. 36 is a cross-sectional view of a semiconductor crystal layer forming wafer 600 produced in the method according to the sixth embodiment.

FIG. 37 is a cross-sectional view illustrating, in the order of steps, a method for producing a semiconductor crystal layer forming wafer according to a seventh embodiment.

FIG. 38 is a cross-sectional view illustrating, in the order of steps, the method for producing a semiconductor crystal layer forming wafer according to the seventh embodiment.

FIG. 39 is a cross-sectional view of a semiconductor crystal layer forming wafer 700 produced in method according to the seventh embodiment.

FIG. 40 is a cross-sectional view of a semiconductor crystal layer forming wafer 800.

FIG. 41 is a cross-sectional view illustrating a method for producing a semiconductor crystal layer forming wafer 900.

FIG. 42 is a cross-sectional view of the semiconductor crystal layer forming wafer 900.

FIG. 43 is a plan view of a semiconductor crystal layer forming wafer 1000 according to an eighth example.

FIG. 44 is a cross-sectional view of the semiconductor crystal layer forming wafer 1000 according to the eighth example.

FIG. 45 is a cross-sectional view illustrating, in the order of steps, a method for producing a composite wafer by using the semiconductor crystal layer forming wafer 1000.

FIG. 46 is a cross-sectional view illustrating, in the order of steps, the method for producing a composite wafer by using the semiconductor crystal layer forming wafer 1000.

FIG. 47 is a cross-sectional view illustrating, in the order of steps, the method for producing a composite wafer by using the semiconductor crystal layer forming wafer 1000.

FIG. 48 is a cross-sectional view illustrating, in the order of steps, the method for producing a composite wafer by using the semiconductor crystal layer forming wafer 1000.

### DESCRIPTION OF EXEMPLARY EMBODIMENTS

Hereinafter, (some) embodiment(s) of the present invention will be described. The embodiment(s) do(es) not limit the invention according to the claims, and all the combinations of the features described in the embodiment(s) are not necessarily essential to means provided by aspects of the invention.

### First Embodiment

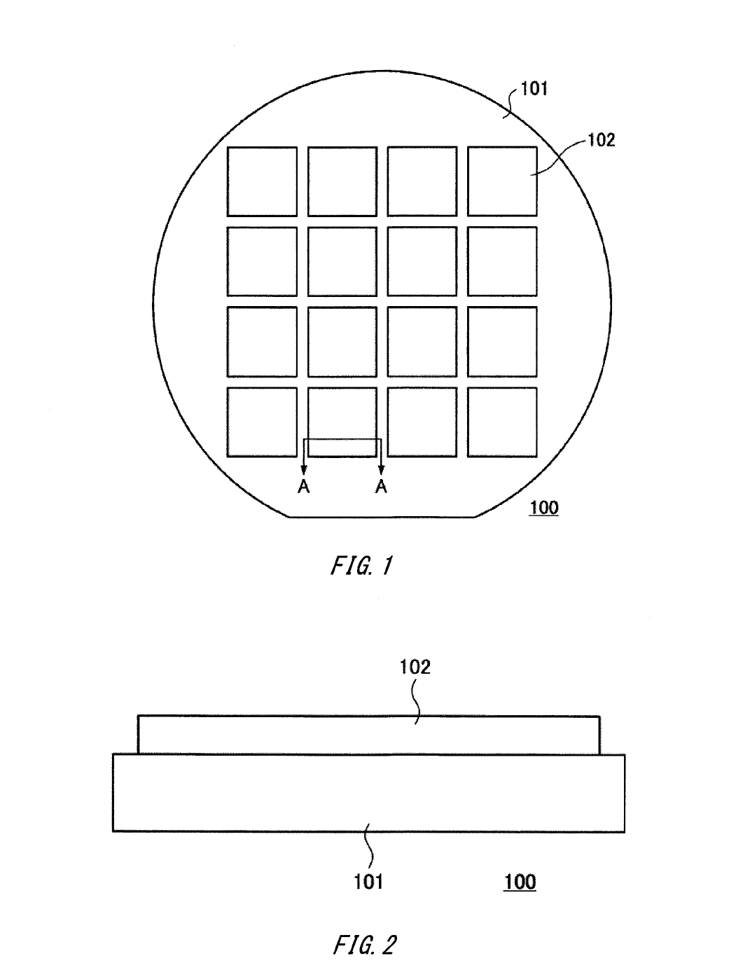

FIG. 1 is a plan view of a semiconductor crystal layer forming wafer 100 to be used in a method for producing a composite wafer according to a first embodiment. FIG. 2 is a cross-sectional view of the semiconductor crystal layer forming wafer 100. FIG. 2 illustrates a cross-section taken along the line A-A in FIG. 1. The semiconductor crystal layer forming wafer 100 has a support wafer 101 and a monocrystal layer 102. The monocrystal layer 102 is supported directly by the front surface or the back surface of the support wafer 101. That is, the monocrystal layer 102 is formed in contact with the front surface or the back surface of the support wafer 101.

The support wafer 101 is preferably not flexible. The support wafer 101 is heat resistant so as to be able to endure the growth temperature in epitaxial growth described below. Examples of the material of the support wafer 101 include silicon, SiC, quartz, sapphire, AlN, polycrystal alumina, polycrystal AlN, glassy carbon, graphite, diamond-like carbon, germanium, and the like. In terms of heat resistance, cost, and readiness of handling in a semiconductor process, the material of the support wafer 101 is preferably a silicon wafer or a germanium wafer. Also, a silicon wafer or a germanium wafer having a front surface on which an oxide layer is formed can be used as the support wafer 101. The support wafer 101 in the present example has a circular shape with a diameter of 200 mm or has any planar shape having an area larger than the circular shape. By using a larger support wafer 101, the productivity (throughput) in producing composite wafers can be improved. Examples of the planar shape include a round shape, a rectangular shape, a square shape, a diamond shape, and the like. Note that in the present specification, the planar shape is a shape in a plane that is parallel to the front surface or the back surface of a wafer such as the support wafer 101.

The monocrystal layer 102 that is supported by the support wafer 101 may cover, entirely or partially, a surface (the front surface or the back surface) of the support wafer 101. The number of the monocrystal layer 102 may be one or more. That is, a plurality of the monocrystal layer 102 may be formed within a surface of a single support wafer 101, or a single monocrystal layer 102 may be formed on a single support wafer 101. When a plurality of the monocrystal layer 102 is formed on a single support wafer 101, the size of the planar shape of the monocrystal layers 102 may be approximately a size of a die, for example, the planar shape may be a square whose one side has the size of approximately 0.5 cm to 3 cm. Alternatively, the planar shape may be a rectangle whose long side or short side has the size of approximately 0.5 cm to 3 cm. Thereby, a semiconductor crystal layer to be formed on a single monocrystal layer 102 can be handled as a wafer for forming a device corresponding to a single die. When a single monocrystal layer 102 is formed on a single support wafer 101, for example, a silicon wafer can be applied as the support wafer 101, and a germanium layer can be applied as the monocrystal layer 102. That is, by using, as the support wafer 101, a silicon wafer about which sufficient skills in terms of handling have been established, and applying germanium as the monocrystal layer 102, epitaxial growth of a compound semiconductor such as GaAs on the monocrystal layer 102 becomes possible. Also, by using silicon for the support wafer 101, the cost can be reduced.

Besides the above-mentioned ones, the planar shape of the monocrystal layer 102 may be a square whose one side has the size of 100 μm or larger and smaller than 0.5 cm. Also, other examples of the planar shape of the monocrystal layer 102 include a rectangle whose one side has the size of approximately 100 μm to 50 cm, and the other side has the size of 50 cm to 100 μm. Furthermore, the planar shape of the monocrystal layer 102 may be a so-called line-and-space pattern in which alternately disposed lines and grooves are spread, the lines having a width of 100 μm to 5 mm (monocrystal layer) and the grooves having a width of 1 μm to 20 mm. Examples of the length of the so-called lines include 5 cm to 50 cm, or the maximum length that is limited by the size of the support wafer 101 (the length between end faces of the support wafer 101). In the present specification, a so-called line-and-space pattern in which 300-μm width lines and 200-μm width grooves are spread is referred to as a “300/200-μm LS pattern” by using the width of lines (line portion) and spaces (groove portion).

The monocrystal layer 102 may be a thin-film crystal layer (monocrystal growth layer) that is formed by film growth such as epitaxial growth. Also, the monocrystal layer 102 may be formed by shaping bulk crystal formed by bulk growth into a plate-like shape such as a wafer-like shape, and further processing the plate-like crystal into an appropriate size, for example, by cleaving. When a thin-film, monocrystal layer (monocrystal growth layer) that is formed by epitaxial growth is used as the monocrystal layer 102, the monocrystal layer 102 can be formed on the support wafer 101 by forming the monocrystal growth layer on the support wafer 101 by using epitaxial growth, and patterning the monocrystal growth layer.

The monocrystal layer 102 is a seed layer for forming a high quality semiconductor crystal layer by epitaxial growth. The preferred material of the monocrystal layer 102 depends on the material of the semiconductor crystal layer that is to be grown epitaxially. In general, the monocrystal layer 102 is desirably made of a material that lattice-match or pseudo-lattice-matches a semiconductor crystal layer to be formed. For example, when an InP layer is formed as a semiconductor crystal layer by epitaxial growth, the monocrystal layer 102 is preferably an InP monocrystal wafer. Also, a monocrystal wafer of sapphire, Ge, SiC or the like can be selected as the monocrystal layer 102. Also, when a GaAs layer or a Ge layer is formed as the semiconductor crystal layer by epitaxial growth, the monocrystal layer 102 is preferably a GaAs monocrystal wafer, and an InP, sapphire, Ge, or SiC monocrystal wafer can be selected. When the monocrystal layer 102 is a GaAs monocrystal wafer or an InP monocrystal wafer, the plane on which the semiconductor crystal layer is formed may be the (100) plane or (111) plane. Note that, because a monocrystal wafer can be selected as the monocrystal layer 102 as described above, the monocrystal layer 102 may be handled as a wafer in the present specification.

The thickness of the monocrystal layer 102 is preferably as large as possible as long as it is not peeled off the support wafer 101. Examples of the thickness of the monocrystal layer 102 include 0.1 to 600 μm, for example. The monocrystal layer 102 is preferably disposed, within a surface of the support wafer 101, by being divided in advance. By dividing and disposing the monocrystal layer 102, a warp of the entire semiconductor crystal layer forming wafer 100 can be suppressed.

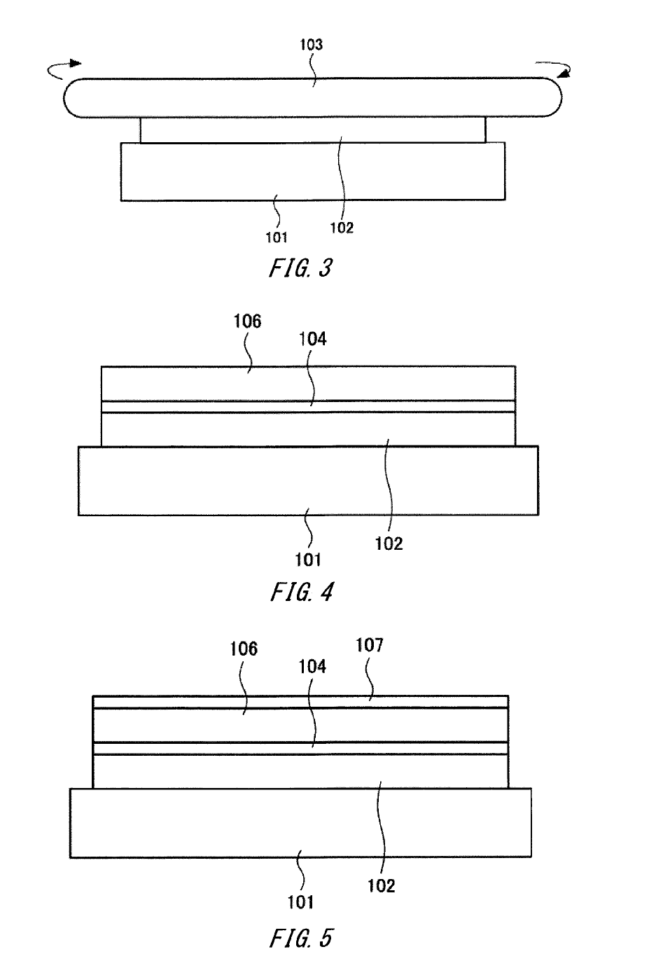

FIGS. 3 to 13 are either cross-sectional views or plan views illustrating, in the order of steps, a method for producing a composite wafer according to the first embodiment. The method for producing a composite wafer is described below in connection with the figures. In the cross-sectional views in the present example, a portion corresponding to a single monocrystal layer 102 is illustrated as in FIG. 2.

As illustrated in FIG. 3, the front surface of the monocrystal layer 102 of the semiconductor crystal layer forming wafer 100 is smoothed. The monocrystal layer 102 can be polished by chemical mechanical polishing (CMP) for example. In the polishing by chemical mechanical polishing, a polishing pad 103 is slid on the front surface of the monocrystal layer 102 while introducing slurry which is a mixture of grinding preparations and a polishing solution. Due to the smoothing step, the front surface of the monocrystal layer 102 can be smoothed, and particles that are generated for example by cleaving of crystal can be removed. Note that this smoothing step is not essential. The smoothing step may be implemented as necessary. Following the smoothing, the front surface of the monocrystal layer 102 may be cleansed.

Next, as illustrated in FIG. 4, a sacrificial layer 104 and a semiconductor crystal layer 106 are formed on the monocrystal layer 102 of the semiconductor crystal layer forming wafer in the order of the monocrystal layer 102, the sacrificial layer 104, and the semiconductor crystal layer 106.

The sacrificial layer 104 is a layer for separating between the monocrystal layer 102 and the semiconductor crystal layer 106. When the sacrificial layer 104 is removed by etching, the monocrystal layer 102 and the semiconductor crystal layer 106 are separated from each other. Because the monocrystal layer 102 and the semiconductor crystal layer 106 need to be left when etching away the sacrificial layer 104, the etching rate of the sacrificial layer 104 is, preferably several times, higher than the etching rates of the monocrystal layer 102 and the semiconductor crystal layer 106. When a GaAs monocrystal wafer is selected as the monocrystal layer 102, and a GaAs layer is selected as the semiconductor crystal layer 106, the sacrificial layer 104 is preferably AlₓGa₁₋ₓAs (0.9≦x≦1) layer, and is more preferably an AlAs layer, and an InAlAs layer, an InGap layer, an InAlP layer, an InGaAlP layer, or an AlSb layer can be selected. Because the crystallinity of the semiconductor crystal layer 106 tends to lower as the thickness of the sacrificial layer 104 becomes larger, the thickness of the sacrificial layer 104 is preferably as small as possible as long as the functionality as the sacrificial layer can be ensured. The thickness of the sacrificial layer 104 can be selected from within the range of 0.1 nm to 10 μm.

The sacrificial layer 104 can be form by CVD (Chemical Vapor Deposition), sputtering, MBE (Molecular Beam Epitaxy), or ALD (Atomic Layer Deposition). Examples of CVD include MOCVD (Metal Organic Chemical Vapor Deposition). MOCVD is used for epitaxial growth of a Group III-V compound semiconductor, and CVD is used for epitaxial growth of a Group IV semiconductor. When the sacrificial layer 104 is formed by MOCVD, examples of the source gas include TMGa (trimethylgallium), TMA (trimethylaluminum), TMIn (trimethylindium), AsH₃ (arsine), PH₃ (phosphine), and the like. Hydrogen can be used as the carrier gas. A compound in which a part of a plurality of hydrogen atom groups of the source gas is substituted with a chlorine atom or a hydrocarbon group can also be used. The reaction temperature can be appropriately selected from within the range of 300° C. to 900° C. and preferably within the range of 400° C. to 800° C. By appropriately selecting the source gas flow rate or the reaction duration, the thickness of the sacrificial layer 104 can be controlled.

The semiconductor crystal layer 106 is a layer that is to be transferred onto a transfer target wafer described below. The semiconductor crystal layer 106 is utilized for an active layer or the like of a semiconductor device.

When the semiconductor crystal layer 106 is formed on the monocrystal layer 102 by epitaxial growth or the like, high quality crystallinity of the semiconductor crystal layer 106 is realized. Furthermore, when the semiconductor crystal layer 106 is transferred onto a transfer target wafer, it becomes possible to form the semiconductor crystal layer 106 on any wafer without considering lattice-matching and the like with the wafer.

Examples of the semiconductor crystal layer 106 include a Ge crystal layer and a GeₓSi₁₋ₓ (0<x<1) crystal layer. The Ge composition ratio x of the GeₓSi₁₋ₓ crystal layer is preferably 0.9 or higher. When the Ge composition ratio x is 0.9 or higher, semiconductor characteristics that are similar to those of a Ge layer can be obtained. By using a (0<x≦1) crystal layer, preferably a GeₓSi₁₋ₓ (0.9<x≦1) crystal layer, or more preferably a Ge crystal layer as the semiconductor crystal layer 106, the semiconductor crystal layer 106 can be used for an active layer of a field effect transistor with high mobility, in particular, of a complementary field effect transistor having high mobility.

The thickness of the semiconductor crystal layer 106 can be appropriately selected from within the range of 0.1 nm to 500 μm. The thickness of the semiconductor crystal layer 106 is preferably no smaller than 0.1 nm but smaller than 1 μm. When the semiconductor crystal layer 106 is smaller than 1 μm, more preferably smaller than 200 nm, and particularly preferably smaller than 20 nm, for example, the semiconductor crystal layer 106 can be used for a composite wafer suited to production of a high performance transistor such as a ultrathin-body MISFET.

The semiconductor crystal layer 106 can be formed by CVD, sputtering, MBE, or ALD. Examples of CVD include MOCVD. When the semiconductor crystal layer 106 is made of a Group III-V compound semiconductor and formed by MOCVD, examples of the source gas include TMGa (trimethylgallium), TMA (trimethylaluminum), TMIn (trimethylindium), AsH₃ (arsine), PH₃ (phosphine), and the like. When the semiconductor crystal layer 106 is made of a Group IV compound semiconductor, and formed by CVD, examples of the source gas include GeH₄ (germane), SiH₄ (silane), Si₂H₆ (disilane), and the like. Hydrogen can be used as the carrier gas. A compound in which a part of a plurality of hydrogen atom groups of the source gas is substituted with a chlorine atom or a hydrocarbon group can also be used. The reaction temperature may be appropriately selected from within the range of 300° C. to 900° C. and preferably within the range of 400° C. to 800° C. By appropriately selecting the source gas flow rate or the reaction duration, the thickness of the semiconductor crystal layer 106 can be controlled.

Next, as illustrated in FIG. 5, an insulating layer 107 is formed on the semiconductor crystal layer 106. The insulating layer 107 may serve as an adhesive layer to adhere to a transfer target wafer. Examples of the insulating layer 107 include an aluminum oxide layer formed by ALD. A silicon oxide layer or a silicon nitride layer formed by CVD may be applied as the insulating layer 107. Note that the insulating layer 107 is not essential, but the insulating layer 107 may be formed as necessary.

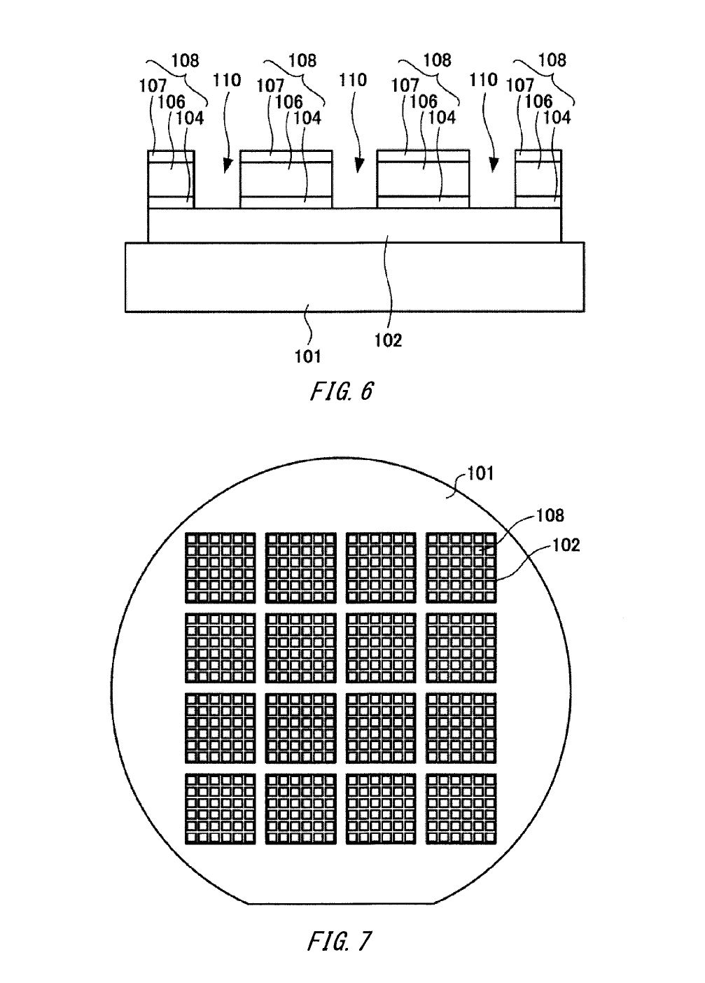

Next, as illustrated in FIG. 6, the insulating layer 107 and the semiconductor crystal layer 106 are etched away so as to expose a part of the sacrificial layer 104, and the insulating layer 107 and the semiconductor crystal layer 106 are divided into plurality of divided pieces 108. The divided pieces 108 have a circular shape with a diameter of 30 mm, or any planar shape smaller than the circle shape. Due to the etching, grooves 110 are formed between adjacent divided pieces 108. Here, the phrase “so as to expose a part of the sacrificial layer 104” may indicate the following cases where the sacrificial layer 104 is substantially exposed in an etching region where the grooves 110 are formed. That is, (1) the sacrificial layer 104 is completely etched away at the bottoms of the grooves 110, the monocrystal layer 102 is exposed at the bottoms of the grooves 110, and a cross-section of the sacrificial layer 104 is exposed as a part of the side surfaces of the grooves 110; (2) the grooves 110 are dug into the monocrystal layer 102, and a cross-section of the sacrificial layer 104 is exposed as a part of the side surfaces of the grooves 110; (3) the sacrificial layer 104 is etched away halfway in a region where the grooves 110 are formed, and the sacrificial layer 104 is exposed at the bottoms of the grooves 110; (4) the semiconductor crystal layer 106 is left at a part of the bottoms of the grooves 110, and a part of the sacrificial layer 104 is exposed at the bottoms of the grooves 110; (5) although a very thin semiconductor crystal layer 106 is left entirely over the bottoms of the grooves 110, but the thickness of the semiconductor crystal layer 106 that has been left is so thin that an etching solution can penetrate therethrough, and the sacrificial layer 104 can be regarded as being substantially exposed.

Any etching method, a dry method or a wet method, can be used in etching to form the grooves 110. In a case of dry etching, halogen gas such as SF₆, CH₄₋ₓFₓ (x=an integer of 1 to 4) can be used as the etching gas. In a case of wet etching, a solution of HCl, HF, phosphoric acid, citric acid, hydrogen peroxide, ammonium, or sodium hydroxide can be utilized as the etching solution. An organic material or an inorganic material having an etching selection ratio can be utilized as an etching mask, and by patterning the mask, a pattern of the grooves 110 can be formed arbitrarily. Note that although it is possible to utilize the monocrystal layer 102 as an etching stopper in the etching to form the grooves 110, the etching of the sacrificial layer 104 is desirably terminated at the front surface or halfway, considering the fact that the monocrystal layer 102 is to be reused. When the semiconductor crystal layer 106 is thin, for example, when the thickness of the semiconductor crystal layer 106 is 2 μm or smaller, it is desirable to dig the grooves 110 to reach the monocrystal layer 102 in some cases.

By forming the grooves 110, the etching solution is introduced from the grooves 110 in the etching of the sacrificial layer 104, and by forming a lot of the grooves 110, the distance that is required to be etched away of the sacrificial layer 104 can be shortened, and the length of time necessary to remove the sacrificial layer 104 can be shortened. FIG. 7 is a plan view of the semiconductor crystal layer forming wafer 100 as seen from above, and a number of divided pieces 108 are formed in the monocrystal layer 102 on the support wafer 101.

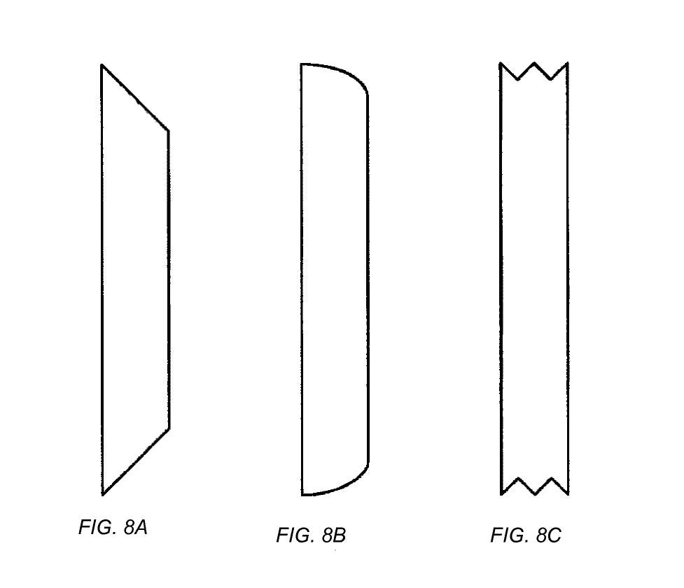

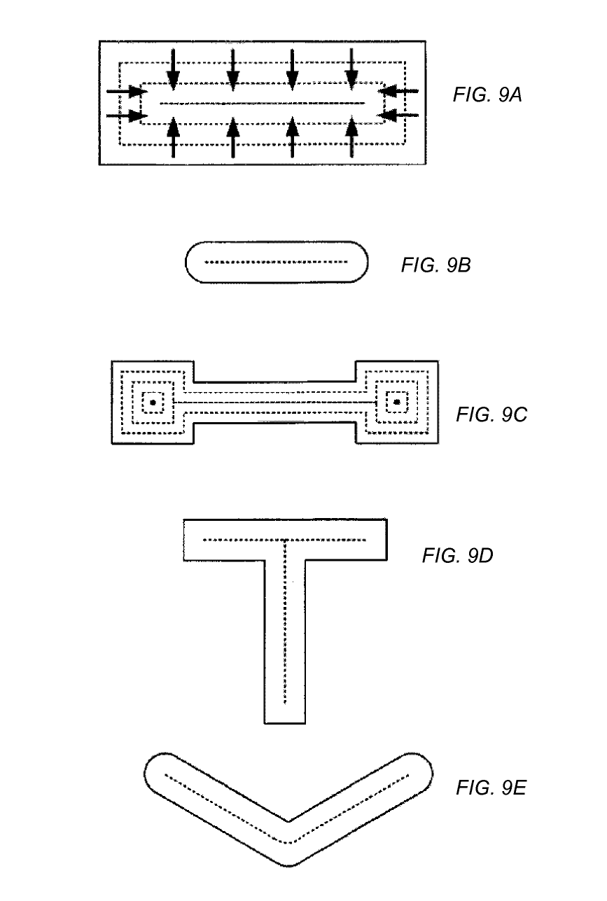

The planar shape of the semiconductor crystal layer 106 that is separated by the pattern of the grooves 110 (the planar shape of the divided pieces 108) is preferably such that when it is assumed that the planar shape shrinks at a constant speed starting from points on the margin of a divided piece 108 in the normal directions at the points, and disappears, the shape observed after the shrinkage and immediately before the disappearance is not a single point, but a single line, a plurality of lines, or a plurality of points. Also, in the assumption, the shrinkage of the planar shape starts simultaneously at the respective points. Here, the margin means a line that indicates the outer shape of the planar shape. Also, the planar shape means a shape in a plane that is vertical to the direction of lamination of each layer. Also, the assumption about the shrinkage and disappearance of the planar shape is made to show the operation of not actually causing the semiconductor crystal layer 106 to shrink and disappear, but of hypothetically causing the semiconductor crystal layer 106 to shrink and disappear for the purpose of defining the planar shape. In the present example, the planar shape before the shrinkage (that is, the actual planar shape of the semiconductor crystal layer 106) is defined by using the shape of the planar shape observed immediately before the disappearance by the operation. Examples of preferred shapes of the divided pieces 108 include a planar shape that is surrounded by two parallel line segments, and two lines that connect the respective end points of the two line segments. However, the planar shape of the semiconductor crystal layer 106 is a shape other than a precise circle and regular polygons. For example, the length of at least one line among the four lines may be different from the length of the other lines. Also, in the planar shape of the semiconductor crystal layer 106, the longest long side may be two or more times longer, four or more times longer, or ten or more times longer than the shortest short side. Also, the lines connecting the end points may be straight lines, curves, or polygonal lines. FIG. 8A illustrates an exemplary planar shape that is formed by connecting the end points of two mutually parallel line segments with straight lines. FIG. 8B illustrates an exemplary planar shape that is formed by connecting the end points of two mutually parallel line segments with curves. FIG. 8C illustrates an exemplary planar shape that is formed by connecting the end points of two mutually parallel line segment with polygonal lines. When the two lines that connect the end points are both straight lines, and two parallel line segments and the straight lines that connect the end points are in a vertical relationship, the planar shape is a rectangle. When the planar shape is a rectangle, if the planar shape of the divided piece shrinks at a constant speed as indicated by arrows in FIG. 9A, the planar shape of the divided piece after the shrinkage as indicated by dotted lines becomes a straight line immediately before it disappears. In a case of a line-and-space pattern in which thin and long line-shaped divided pieces 108 are repeatedly disposed, or in a case of a rectangle whose corners are replaced with curves (rounded rectangle) as illustrated in FIG. 9B, the shape that is observed immediately before it disappears becomes a straight line like the rectangle of FIG. 9A. In a case of an I-shape as illustrated in FIG. 9C, the planar shape that is observed immediately before it disappears converges to two points. In a case of a T-shape as illustrated in FIG. 9D or a gull wing-shape as illustrated in FIG. 9E, the planar shape observed immediately before it disappears is a combination of straight lines or a curve.

In the step of etching away the sacrificial layer 104, the semiconductor crystal layer 106 receives force in a direction away from the monocrystal layer 102 due to a gaseous product. Then, if the remnant of the sacrificial layer 104 concentrates at a single point immediately before the sacrificial layer 104 is entirely dissolved, the force concentrates at the single point in the remaining portion of the sacrificial layer 104. In such a situation, the semiconductor crystal layer 106 and the monocrystal layer 102 are separated from each other by relatively large force, and the semiconductor crystal layer 106 is damaged due to the shock that is caused at the time of separation. For this reason, a hole or a concave portion may occur near the center of the pattern of the transferred semiconductor crystal layer 106. However, by employing the shapes as illustrated in FIGS. 8A to 8C, and 9A to 9E as the planar shape of the divided pieces 108, the remaining portion of the sacrificial layer 104 becomes not a single point but a plurality of points or a straight line, and the shock that is caused when the semiconductor crystal layer 106 is separated from the monocrystal layer 102 can be mitigated. Thereby, occurrence of a hole or a concave portion near the center of the pattern of the planar shape of the transferred semiconductor crystal layer 106 can be suppressed, and transfer defects can be reduced.

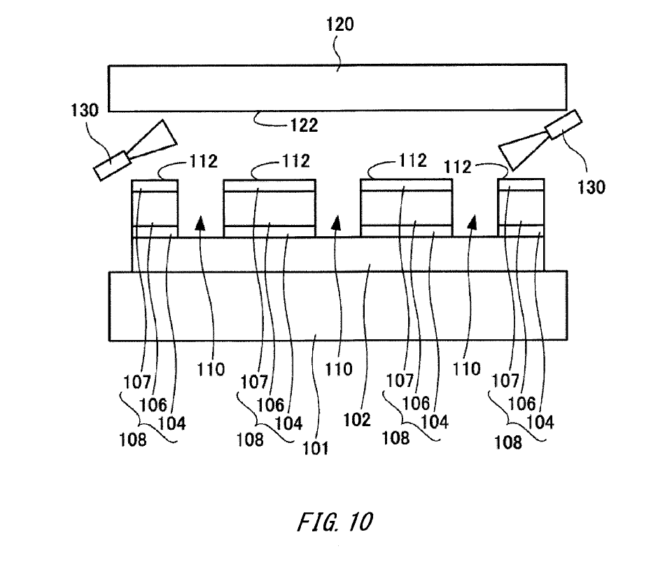

Next, as illustrated in FIG. 10, adhesiveness enhancement treatment to enhance the adhesiveness between the transfer target wafer 120, and the insulating layer 107 and the semiconductor crystal layer 106 is performed on the front surface of the transfer target wafer 120 and the front surface of the insulating layer 107. Here, the front surface of the insulating layer 107 at portions other than the grooves 110 on the monocrystal layer 102 is one example of “a first front surface 112” that is the front surface of a layer formed on the monocrystal layer 102, and is to contact the transfer target wafer 120 or a layer formed on the transfer target wafer 120. Also, the front surface of the transfer target wafer 120 is one example of a “second front surface 122” that is the front surface of the transfer target wafer 120 or a layer formed on the transfer target wafer 120, and is to contact the first front surface 112.

The adhesiveness enhancement treatment may be performed only on one of the front surface of the transfer target wafer 120 (the second front surface 122) or the front surface of the insulating layer 107 (the first front surface 112). Examples of the adhesiveness enhancement treatment include ion beam activation by an ion beam generator 130. Ions to be irradiated are argon ions for example. Plasma activation may be performed as the adhesiveness enhancement treatment. Examples of the plasma activation processing include oxygen plasma processing. The adhesiveness enhancement treatment can enhance the adhesiveness between the transfer target wafer 120 and the insulating layer 107. Note that the adhesiveness enhancement treatment is not essential. Instead of the adhesiveness enhancement treatment, an adhesive layer may be formed on the transfer target wafer 120 in advance.

The transfer target wafer 120 is a wafer onto which the semiconductor crystal layer 106 is transferred. The transfer target wafer 120 may be a target wafer on which an electronic device that utilizes the semiconductor crystal layer 106 as an active layer is eventually disposed, or may be a wafer on which the semiconductor crystal layer 106 is tentatively placed before it is transferred onto a target wafer in an intermediate state. The transfer target wafer 120 may be an organic material or an inorganic material. Examples of the transfer target wafer 120 include silicon wafer, a SOI (Silicon on Insulator) wafer, a glass wafer, a sapphire wafer, a SiC wafer, and an AIN wafer. Other than them, the transfer target wafer 120 may be an insulator wafer such as a ceramic wafer or a plastic wafer, or a conductor wafer such as a metal. When a silicon wafer or a SOI wafer is used as the transfer target wafer 120, production devices that are used in existing silicon processes can be utilized, and knowledge about the already known silicon processes can be utilized to enhance the efficiency of research and development, and of production. When the transfer target wafer 120 is a hard wafer such as a silicon wafer that cannot be readily bent, the semiconductor crystal layer 106 to be transferred can be protected from mechanical vibrations and the like, and the crystal quality of the semiconductor crystal layer 106 can be kept high.

Note that a heat resistant insulating layer may be formed on the transfer target wafer 120. Examples of the heat resistant insulating layer include Al₂O₃ formed by ALD, and SiO₂ and Si₃N₄ formed by CVD. The transfer target wafer 120 preferably has a circular shape with a diameter of 200 mm, or any planar shape having an area larger than the circular shape. By using a large transfer target wafer 120, the productivity can be enhanced. Note that examples of the planar shape include a round shape, a rectangular shape, a square shape, a diamond shape, and the like.

Next, as illustrated in FIG. 11, the front surface (the second front surface 122) of the transfer target wafer 120 is caused to face the front surface (the first front surface 112) of the insulating layer 107, and the transfer target wafer 120 and the semiconductor crystal layer forming wafer 100 are bonded. In the bonding, the transfer target wafer 120 and the semiconductor crystal layer forming wafer 100 are bonded such that the front surface of the insulating layer 107 which is the first front surface 112 is joined with the front surface of the transfer target wafer 120 which is the second front surface 122. When the adhesiveness enhancement treatment is performed, the bonding can be performed at room temperature. In the bonding, the semiconductor crystal layer forming wafer 100 and the transfer target wafer 120 may be attached under pressure. The pressure range in this case can be appropriately selected from within the range of 0.01 MPa to 1 GPa. The attachment under pressure can improve the adhesion strength. Heating may be performed at the time of or after the attachment under pressure. The heating temperature is preferably 50 to 600° C., and more preferably 100° C. to 400° C. Note that the semiconductor crystal layer forming wafer 100 and the transfer target wafer 120 may be attached under pressure within the above-mentioned pressure range at the same time when they are bonded.

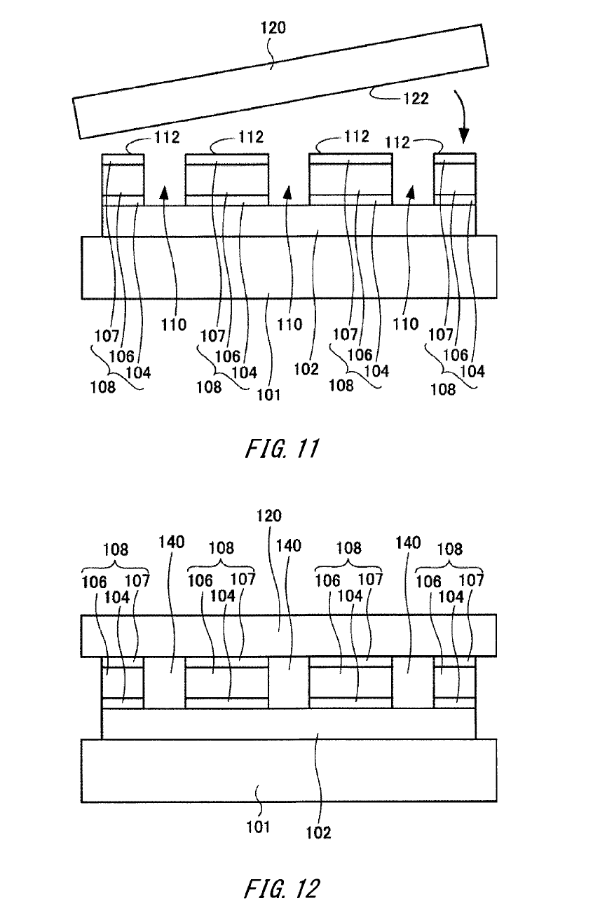

Due to the bonding, as illustrated in FIG. 12, a cavity 140 is formed by the inner walls of the grooves 110 and the front surface of the transfer target wafer 120. By introducing an etching solution 142 into the cavity 140, the sacrificial layer 104 is etched away. Note that the etching may be dry etching by using etching gas. When the sacrificial layer 104 is an AlAs layer, examples of the etching solution 142 include solutions of HCl, HF, phosphoric acid, citric acid, hydrogen peroxide solution, ammonium, and sodium hydroxide, and water. The temperature during the etching is preferably controlled to be within the range of 10 to 90° C. The duration of the etching is appropriately controlled within the range of 1 minute to 200 hours.

Examples of the method for introducing the etching solution 142 into the cavity 140 include the following methods: a method of introducing the etching solution 142 into the cavity 140 by utilizing the capillary phenomenon; a method of forcibly introducing the etching solution 142 into the cavity 140 by immersing one end of the cavity 140 in the etching solution 142, and suctioning the etching solution 142 from the other end; and in a case that one end of the cavity 140 is open, and the other end is closed, a method of forcibly introducing the etching solution 142 into the cavity 140 by placing the transfer target wafer 120 and the semiconductor crystal layer forming wafer 100 in a depressured condition, immersing the open end of the cavity 140 in the etching solution 142, and then placing the transfer target wafer 120 and the semiconductor crystal layer forming wafer 100 in the atmospheric pressure condition.

Specific examples of the method of introducing the etching solution 142 into the cavity 140 by using the capillary phenomenon include a method of dripping the etching solution 142 into one end of the cavity 140 by using a micro pipetter or the like. In order to introduce the etching solution 142 into the cavity 140 by utilizing the capillary phenomenon, the other end of the cavity 140 needs to be open. When the etching solution 142 is introduced into the cavity 140 by dripping the etching solution 142 into one end of the cavity 140, the etching solution 142 can be introduced into the cavity 140 simply, easily and surely. Note that after the inner part of the cavity 140 is filled with the etching solution 142, the transfer target wafer 120 and the semiconductor crystal layer forming wafer 100 can be entirely immersed in an etching bath filled with the etching solution 142 to proceed with the etching. Alternatively, it is possible to proceed with the etching by keeping introducing the etching solution 142 to one end of the cavity 140. When the etching solution 142 is introduced into one end of the cavity 140 by dripping, the amount of the etching solution 142 to be used can be very small so that the etching solution 142 can be reduced, and it is possible to try to reduce the cost, and to reduce the environmental burden that accompanies disposal of the etching solution 142.

Also, when the cavity 140 is immersed in the etching solution 142, grease may be attached to a part of the side surface of a bonded wafer. In this case, by attaching the grease to the side surface of the wafer, penetration of the etching solution into the inner part of the cavity 140 from the side surface can be suppressed. When the inner part of the cavity 140 is to be filled with the etching solution by using the capillary phenomenon, if the etching solution penetrates from the side surface, the capillary phenomenon is inhibited, and the inner part of the cavity 140 may not be filled sufficiently with the etching solution. However, penetration of the etching solution from the side surface of the wafer can be suppressed by attaching the grease on the side surface, and the inner part of the cavity 140 can be surely filled with the etching solution. Note that the material is not limited to grease, and other materials can be used as long as penetration of the etching solution from the side surface can be suppressed.

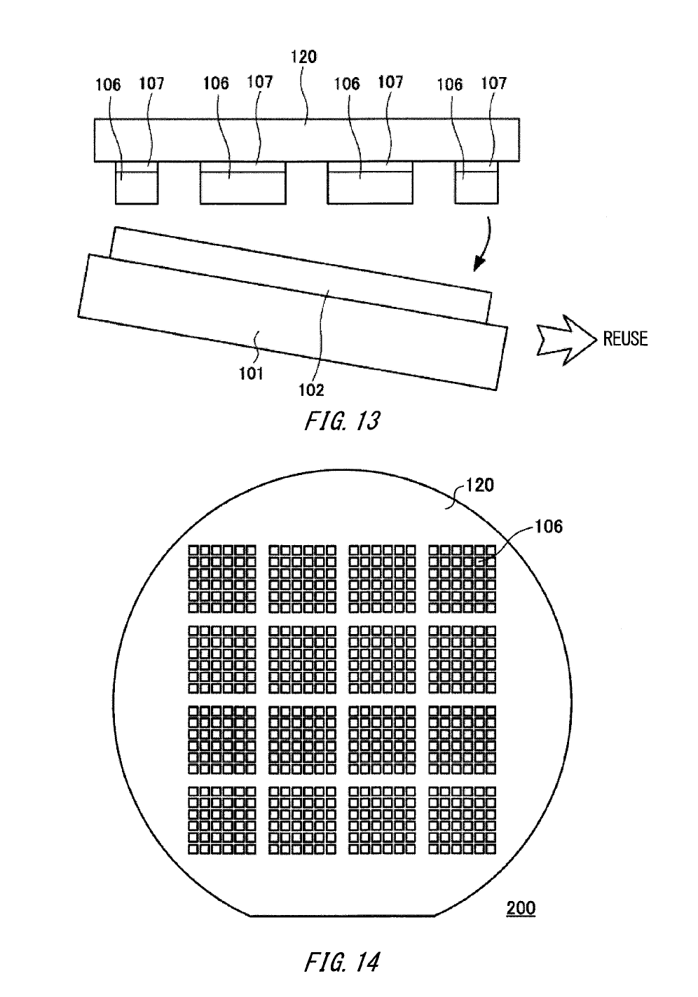

When the sacrificial layer 104 is removed by performing etching, as illustrated in FIG. 13, the transfer target wafer 120 and the monocrystal layer 102 (the semiconductor crystal layer forming wafer 100) are separated from each other in a state that the semiconductor crystal layer 106 is left on the transfer target wafer 120 side. Thereby, the semiconductor crystal layer 106 is transferred onto the transfer target wafer 120, and a composite wafer having the semiconductor crystal layer 106 on the transfer target wafer 120 can be produced. The semiconductor crystal layer 106 on the transfer target wafer 120 is, as illustrated in FIG. 14, formed as a number of divided pieces.

Also, the separated semiconductor crystal layer forming wafer 100 is reused, and similarly utilized starting from the smoothing step illustrated in FIG. 3. The semiconductor crystal layer forming wafer 100 can be reused until the monocrystal layer 102 is consumed and can no longer be used, and it can be expected to significantly reduce the production cost thanks to the reuse.

### Second Embodiment

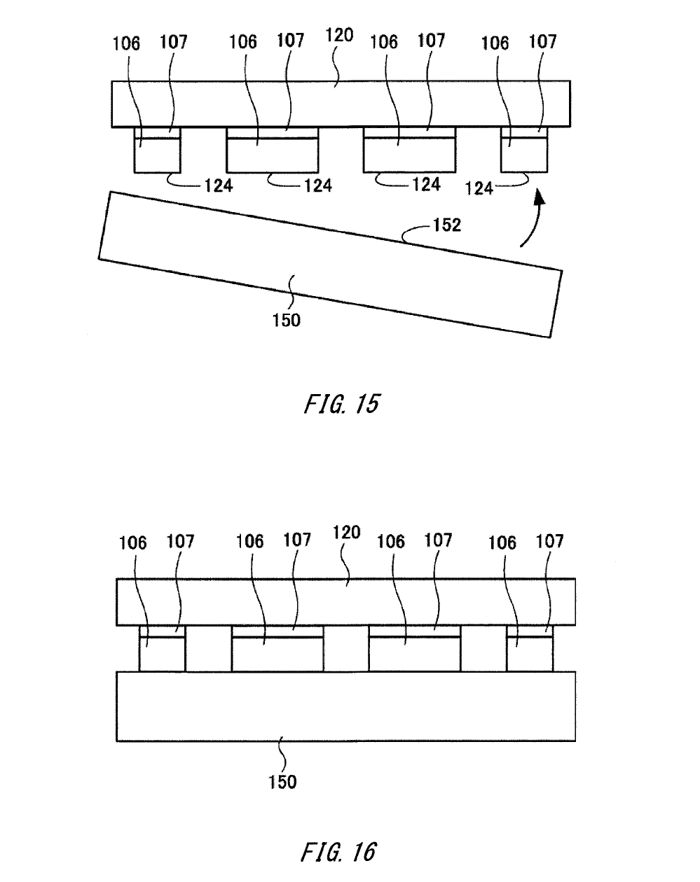

FIGS. 15 to 17 are cross-sectional views illustrating, in the order of steps, a method for producing a composite wafer according to a second embodiment. In the second embodiment, a composite wafer produced by the method according to the first embodiment (a composite wafer having the semiconductor crystal layer 106 on the transfer target wafer 120) is used. In the method for producing a composite wafer having the semiconductor crystal layer 106 on a second transfer target wafer 150 according to the second embodiment, the semiconductor crystal layer 106 on the transfer target wafer 120 is further transferred onto the second transfer target wafer 150.

As illustrated in FIG. 15, the front surface (a third front surface 124) of the semiconductor crystal layer 106 on the transfer target wafer 120 is caused to face the front surface (a fourth front surface 152) of the second transfer target wafer 150, and as illustrated in FIG. 16, the transfer target wafer 120 and the second transfer target wafer 150 are bonded to each other. Note that the front surface of the semiconductor crystal layer 106 is one example of the third front surface 124 that is the front surface of the semiconductor crystal layer 106 on the transfer target wafer 120 or the front surface of a layer formed on the semiconductor crystal layer 106, and is to contact the second transfer target wafer 150 or a layer formed on the second transfer target wafer 150. Also, the front surface of the second transfer target wafer 150 is one example of the fourth front surface 152 that is the front surface of the second transfer target wafer 150 or a layer formed on the second transfer target wafer 150, and is to contact the third front surface 124.

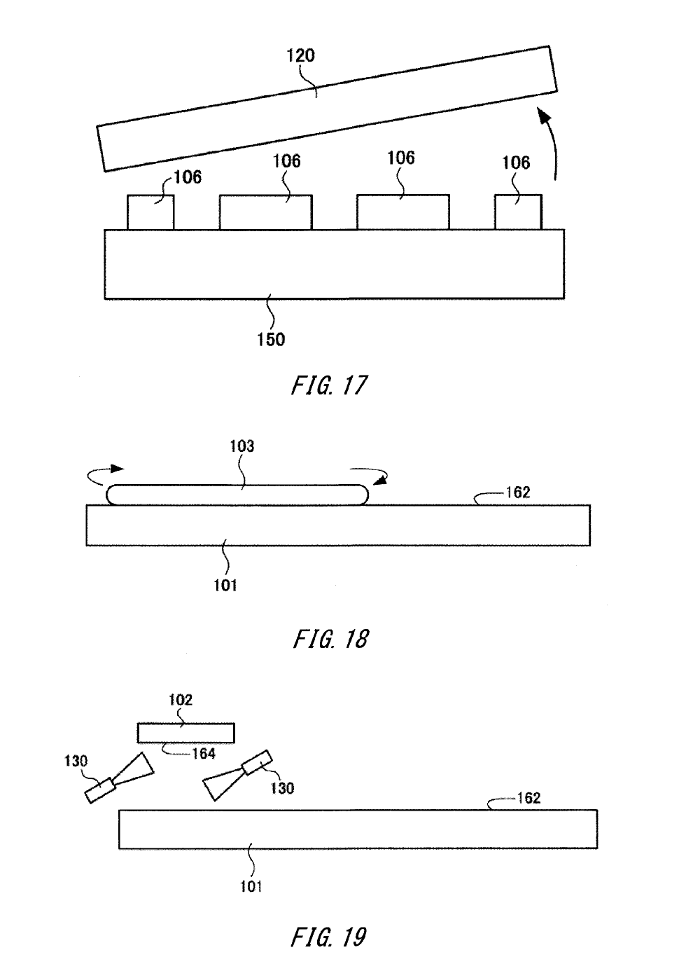

Next, as illustrated in FIG. 17, the insulating layer 107 is removed, and the transfer target wafer 120 and the second transfer target wafer 150 are separated from each other in a state that the semiconductor crystal layer 106 is left on the second transfer target wafer 150. Note that although the insulating layer 107 is caused to serve as the adhesive layer in the first embodiment, it is here caused to serve as a sacrificial layer used for peeling.

In the second embodiment, the insulating layer 107 to serve as both an adhesive layer and a sacrificial layer may be provided, and a sacrificial layer separate from the insulating layer 107 may be formed.

In this manner, the semiconductor crystal layer 106 can be transferred onto the second transfer target wafer. It is needless to say that the semiconductor crystal layer 106 may be transferred onto a still another transfer target wafer. Note that the transfer target wafer 120 may be a flexible organic material wafer such as a film. In this case, peeling can be readily performed by dissolving or swelling the organic material wafer by an organic solvent or the like.

### Third Embodiment

FIGS. 18 to 21 are cross-sectional views illustrating, in the order of steps, a method for producing a semiconductor crystal layer forming wafer according to a third embodiment. In the third embodiment, a method for producing the semiconductor crystal layer forming wafer 100 used in the first embodiment is described.

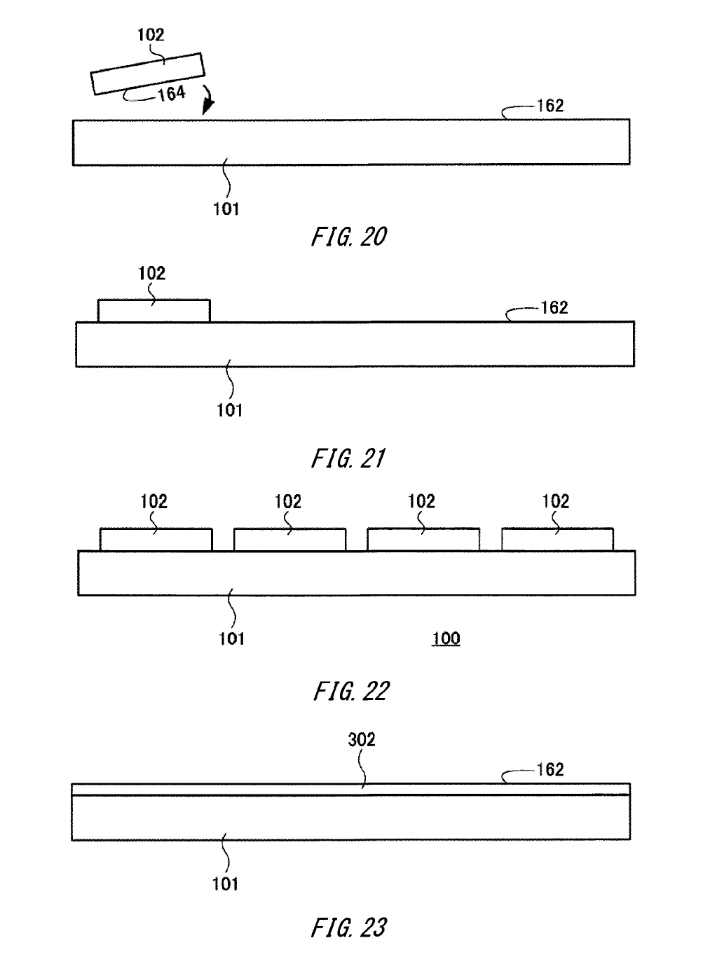

First, as illustrated in FIG. 18, one or more front surfaces select from among a fifth front surface 162 of the support wafer 101 to contact the monocrystal layer 102 and a sixth front surface 164 of the monocrystal layer 102 to contact the support wafer 101 are smoothed. The monocrystal layer 102 in the present example is a monocrystal wafer. Examples of the smoothing process include CMP as described previously. Next, as illustrated in FIG. 19, one or more front surfaces selected from among the fifth front surface 162 and the sixth front surface 164 is/are activated. Argon ion beam can be used for the activation as described previously. Next, as illustrated in FIG. 20, the fifth front surface 162 is caused to face the sixth front surface 164, and as illustrated in FIG. 21, the support wafer 101 and the monocrystal layer 102 are bonded to each other. Examples of the temperature of the support wafer 101 and the monocrystal layer 102 in the bonding include −20° C. to 80° C. that is similar to the use temperature range of parts produced by utilizing the composite wafer according to the embodiments of the present invention, and the temperature is preferably 0° C. to 60° C. that is the normal use temperature range of devices, and is further preferably 20° C. to 30° C. that is the temperature range of normal temperature during the bonding process. The support wafer 101 and the monocrystal layer 102 may be attached to each other under pressure, and in this case, the pressure range is preferably 0.01 MPa to 1 GPa. By performing the above-mentioned step on a plurality of the monocrystal layers 102, the semiconductor crystal layer forming wafer 100 can be produced as illustrated in FIG. 22.

According to the method for producing the semiconductor crystal layer forming wafer 100 as mentioned above, because surfaces between the support wafer 101 and the monocrystal layer 102 are smoothed and activated, the support wafer 101 and the monocrystal layer 102 are firmly adhered, and it is possible to produce a semiconductor crystal layer forming wafer 100 that does not peel off easily even if it receives thermal stress due to a temperature rise/fall in the layer forming processes such as epitaxial growth. Note that the flatness of the support wafer 101 or the monocrystal layer 102 can be made 0.5 nm or lower in terms of the root-mean square roughness (R_{RMS}) due to the smoothing by CMP.

### Fourth Embodiment

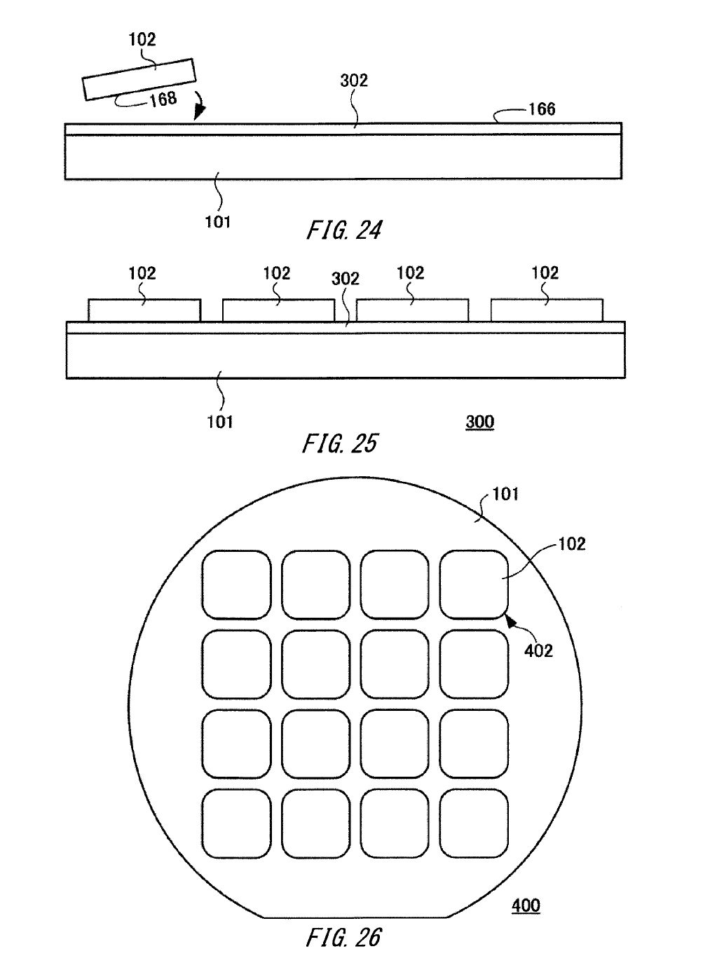

FIGS. 23 and 24 are cross-sectional views illustrating, in the order of steps, a method for producing a semiconductor crystal layer forming wafer according to a fourth embodiment. While in the third embodiment, the case where the support wafer 101 and the monocrystal layer 102 are caused to directly contact each other was described, a heat resistant intermediate layer 302 may be formed on the support wafer 101 as illustrated in FIG. 23, and the monocrystal layer 102 may be bonded to the intermediate layer 302 as illustrated in FIG. 24. By performing bonding similarly on a plurality of the monocrystal layers 102, a semiconductor crystal layer forming wafer 300 can be produced as illustrated in FIG. 25. That is, the heat resistant intermediate layer 302 is formed on one or more front surfaces selected from among the front surface that is positioned on the monocrystal layer 102 side of the support wafer 101, and the front surface that is positioned on the support wafer 101 side of the monocrystal layer 102. In addition, a seventh front surface 166 that is the front surface of the support wafer 101 or the intermediate layer 302 formed on the support wafer 101 and is to contact the monocrystal layer 102 or the intermediate layer 302 formed on the monocrystal layer 102 is caused to face an eighth surface 168 that is the front surface of the monocrystal layer 102 or the intermediate layer 302 formed on the monocrystal layer 102, and is to contact the seventh front surface 166, and the support wafer 101 and the monocrystal layer 102 can be bonded to each other. Note that, of course the semiconductor crystal layer forming wafer 300 according to the present fourth embodiment may be used in the first embodiment.

For example, an aluminum oxide layer formed by ALD, or a silicon oxide layer or a silicon nitride layer formed by CVD can be used for the intermediate layer 302. In the present fourth embodiment, after forming the intermediate layer 302, and before bonding, one or more front surfaces selected from among the seventh front surface 166 and the eighth surface 168 can be activated. Also, after forming the intermediate layer 302, and before the activation, one or more front surfaces selected from among the seventh front surface 166 and the eighth surface 168 can be smoothed.

Note that although a square shape is mentioned as the planar shape of the monocrystal layer 102 in the above-mentioned embodiment, the planar shape of the monocrystal layer 102 is not limited to a square shape, but may be any shape such as a rectangular shape, other polygonal shapes, a round shape, or an elliptical shape. However, when the planar shape of the monocrystal layer 102 bonded to the support wafer 101 has corners 402, as illustrated in FIG. 26, after bonding the support wafer 101 and the monocrystal layer 102 to each other, processing to round the corners 402 of the monocrystal layer 102 in the planar shape is preferably performed. By rounding the corners 402, peeling from the corners 402 can be reduced. Examples of methods of processing to round the corners 402 include isotropic etching, and wet or dry etching after a mask is formed.

### Fifth Embodiment

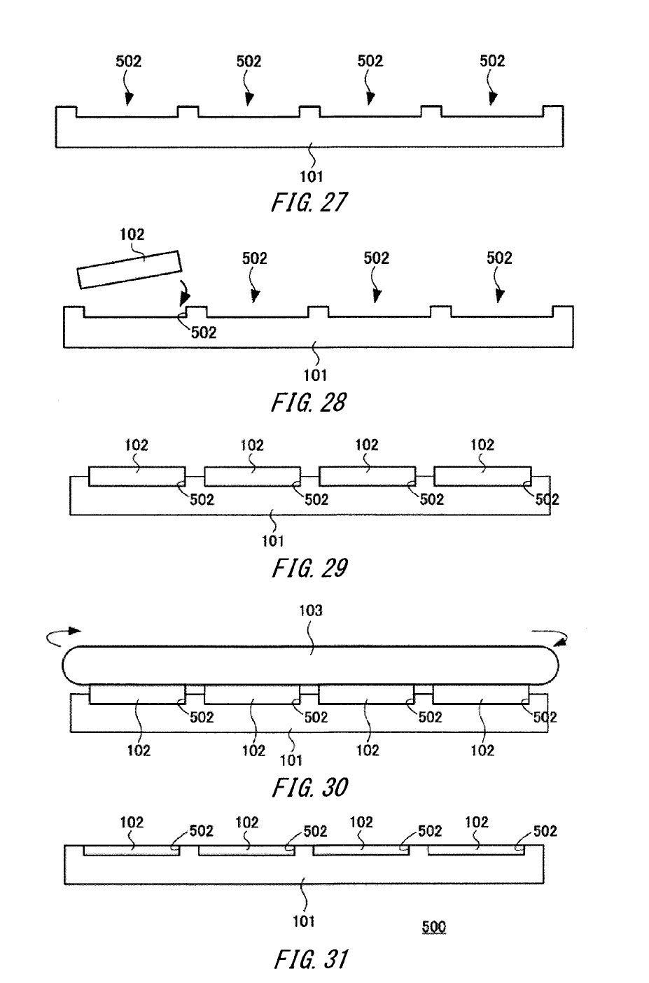

FIGS. 27 to 30 are cross-sectional views illustrating, in the order of steps, a method for producing a semiconductor crystal layer forming wafer according to a fifth embodiment. FIG. 31 is a cross-sectional view of a semiconductor crystal layer forming wafer 500 produced in the method according to the fifth embodiment. In the fifth embodiment, a method for producing a semiconductor crystal layer forming wafer that is different from those according to the third embodiment and the fourth embodiment is described.

Before forming the monocrystal layer 102 on the support wafer 101, concave portions 502 are formed on the support wafer 101 as illustrated in FIG. 27. For example, the concave portions 502 can be formed by forming a mask such as a photoresist on the support wafer 101, and etching away the support wafer 101 in a region that is not covered by the mask by dry etching or the like.

Then, as illustrated in FIG. 28. The monocrystal layer 102 is formed on the concave portions 502. For example, the monocrystal layer 102 may be formed on the concave portions 502 by bonding the monocrystal layer 102 to the support wafer 101 as in the third embodiment or the fourth embodiment. By processing the monocrystal layer 102 to have a size that is adapted to the concave portions 502 in advance, aligning at the time of bonding becomes easy, and the bonding can be performed accurately.

As illustrated in FIG. 29, the monocrystal layer 102 is bonded to and formed on all the concave portions 502, and as illustrated in FIG. 30, the front surface of the monocrystal layer 102 is polished by the polishing pad 103. This polishing is performed such that the front surface of the monocrystal layer 102 formed on the concave portions 502 becomes substantially flush with the front surface of the support wafer 101. That is, the polishing ends when the front surface of the monocrystal layer 102 becomes substantially flush with the front surface of the support wafer 101. Thereby, as illustrated in FIG. 31, the semiconductor crystal layer forming wafer 500 is formed.

Because the semiconductor crystal layer forming wafer 500 is formed such that the front surface of the monocrystal layer 102 becomes substantially flush with the front surface of the support wafer 101, when the semiconductor crystal layer forming wafer 500 is used in epitaxial growth or the like to form the semiconductor crystal layer 106, the gas flow in the epitaxial growth is not disturbed, and a uniform semiconductor crystal layer 106 can be formed. Also, because the monocrystal layer 102 has been polished, and thus has become thin, even if stress such as a warp of the monocrystal layer 102 occurs due to the rise of the wafer temperature in epitaxial growth or the like, peeling is difficult to occur, and the semiconductor crystal layer forming wafer 500 can be made thermally stable.

Note that because the description referring to FIG. 30 is about the case where the front surface of the monocrystal layer 102 before the polishing protrudes above the front surface of the support wafer 101, the subject to be polished by the polishing pad 103 was the front surface of the monocrystal layer 102. In contrast to this, the monocrystal layer 102 may be formed to be thin, and the front surface of the monocrystal layer 102 may be depressed relative to the front surface of the support wafer 101. In this case, the subject to be polished by the polishing pad 103 is the front surface of the support wafer 101.

Although in the above-mentioned fifth embodiment, an example in which the monocrystal layer 102 is formed on the concave portions 502 was described, convex portions may be formed on the support wafer 101 before forming the monocrystal layer 102 on the support wafer 101, and the monocrystal layer 102 may be formed on the convex portions. In this case, when the monocrystal layer 102 is bonded to and formed on the support wafer 101, the monocrystal layer 102 can self-align with and be formed on the convex portions.

### Sixth Embodiment

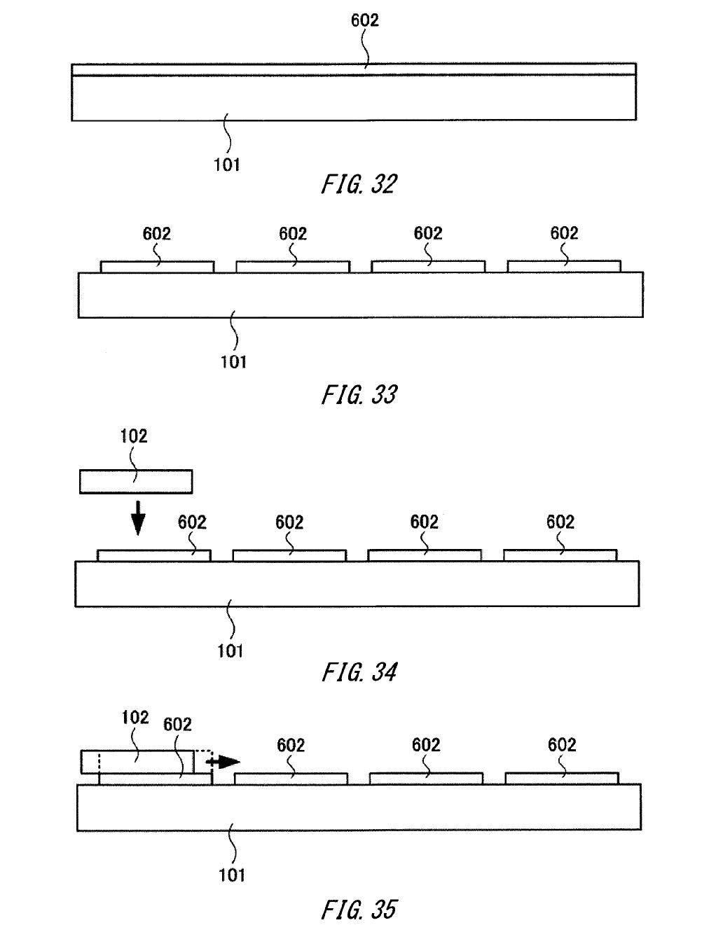

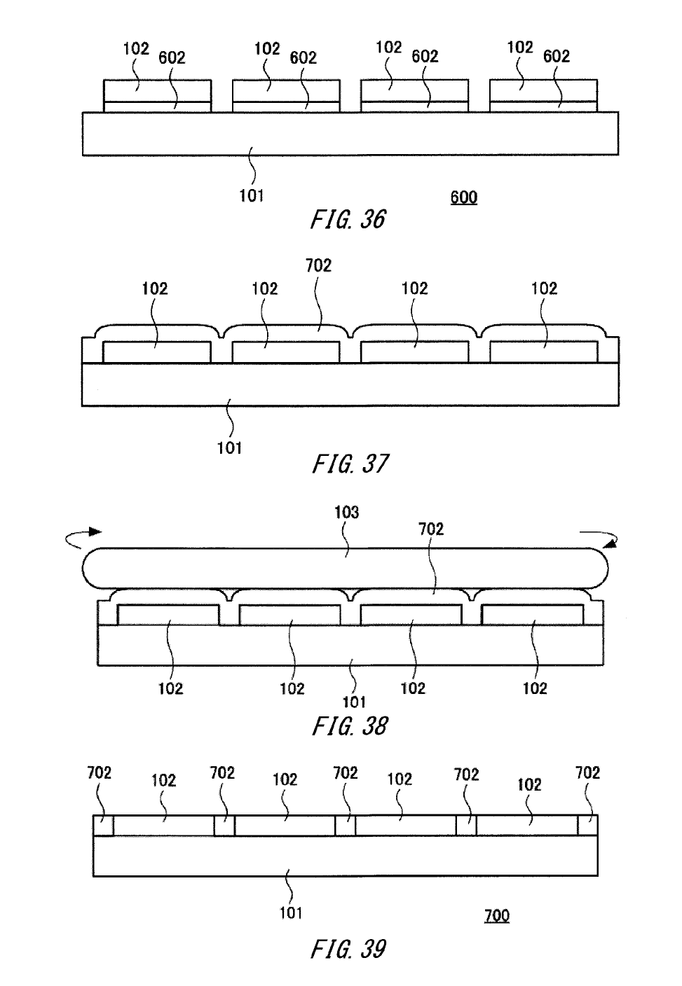

FIGS. 32 to 35 are cross-sectional views illustrating, in the order of steps, a method for producing a semiconductor crystal layer forming wafer according to a sixth embodiment. FIG. 36 is a cross-sectional view of a semiconductor crystal layer forming wafer 600 produced in the method according to the sixth embodiment. In the sixth embodiment, a method for producing a semiconductor crystal layer forming wafer that is further different from those of the third embodiment to the fifth embodiment is described.

As illustrated in FIG. 32, an insulating layer 602 is formed on the support wafer 101. The insulating layer 602 is a natural oxide layer for example. For example, the insulating layer 602 may be a layer of Al₂O₃, HfO₂, ZrO₂, or La₂O₃ formed by ALD, or a layer of HfO₂, ZrO₂, La₂O₃, or SiO₂ formed by MOCVD. The thickness of the insulating layer 602 can be within the range of 1 nm to 15 nm for example.

As illustrated in FIG. 33, a part of the insulating layer 602 is removed by patterning. The removal of the part of the insulating layer 602 is one example of surface processing on a region of the support wafer 101 where the monocrystal layer 102 is formed or is not formed, and is one example of hydrophilization or hydrophobization of the front surface of the support wafer 101. Depending on the material of the insulating layer 602 and depending on the presence or absence of the insulating layer 602, a hydrophilized or a hydrophobized region can be formed. That is, when a partial region of the front surface of the support wafer 101 is desired to be hydrophilized, an insulating layer 602 having hydrophilicity higher than that of the support wafer 101 is formed in the partial region. Also, when a partial region of the front surface of the support wafer 101 is desired to be hydrophobized, an insulating layer 602 having hydrophobicity higher than that of the support wafer 101 is formed in the partial region. In the present example, an insulating layer 602 having hydrophilicity higher than that of the support wafer 101 is formed in the partial region of the front surface of the support wafer 101.

Next, as illustrated in FIG. 34, the front surface of the insulating layer 602 is caused to face the front surface of the monocrystal layer 102, and the support wafer 101 and the monocrystal layer 102 are bonded to each other. As this time, the monocrystal layer 102 is handled by a chip sorter or the like, and roughly aligned. The monocrystal layer 102 self-aligns with and is positioned relative to the support wafer 101 due to the surface tension of water that is present between a hydrophilized portion or a unhydrophobized portion of the front surface of support wafer 101 and the front surface of the monocrystal layer 102 as illustrated in FIG. 35, because at the time of the bonding, the front surface of the support wafer 101 has been hydrophilized by the insulating layer 602. The water may be introduced onto the front surface of the support wafer 101 after the formation of the insulating layer 602. Thereby, even if the alignment by the chip sorter is roughly performed, accurate alignment is possible, and positional variation, such as differences in crystal orientations due to positional displacement, that can possibly lead to deterioration of the performance of electronic devices can be reduced.

As illustrated in FIG. 36, all the necessary monocrystal layers 102 are disposed on the support wafer 101. Note that a plurality of the monocrystal layers 102 may be disposed by picking up each one of them, or may be handled simultaneously in the unit of multiple monocrystal layers 102. In this manner, the semiconductor crystal layer forming wafer 600 is formed. That is, before forming the monocrystal layer 102 on the support wafer 101, surface processing is performed on a region in which the monocrystal layer 102 of the support wafer 101 is formed or is not formed. Then, at the step of forming the monocrystal layer 102, the monocrystal layer 102 is formed by being caused to self-align with a region on which the surface processing has or has not been performed.

Because the thus-formed semiconductor crystal layer forming wafer 600 is formed by causing the monocrystal layer 102 to self-align relative to the support wafer 101, the monocrystal layer 102 is formed while being aligned accurately on the support wafer 101. If there are differences in crystal orientations due to positional displacement of the monocrystal layer 102, differences in crystal orientations occur also in the semiconductor crystal layer 106 formed by using the semiconductor crystal layer forming wafer 600, and this may possibly lead to performance deterioration of electronic devices. However, in the case of the semiconductor crystal layer forming wafer 600, such defects are suppressed.

Note that after forming the monocrystal layer 102 on the support wafer 101, the monocrystal layer 102 may be made thin. By making the monocrystal layer 102 thin, peeling and the like become difficult to occur even when the support wafer 101 and the monocrystal layer 102 receive thermal stress. Also, when a plurality of the monocrystal layers 102 is formed on a single support wafer 101, and the plurality of monocrystal layers 102 is made thin, all the monocrystal layers 102 on the support wafer 101 are made thin preferably by polishing the front surfaces of the monocrystal layers 102 simultaneously. By polishing the front surfaces of all the monocrystal layers 102 simultaneously, the front surfaces of the monocrystal layers 102 can be made substantially flush.

### Seventh Embodiment

FIGS. 37 and 38 are cross-sectional views illustrating, in the order of steps, a method for producing a semiconductor crystal layer forming wafer according to a seventh embodiment. FIG. 39 is a cross-sectional view illustrating, in the order of steps, a method for producing the semiconductor crystal layer forming wafer 700 according to the seventh embodiment. In the seventh embodiment, like the semiconductor crystal layer forming wafer 100 illustrated in FIG. 22, a plurality of the monocrystal layers 102 is formed on a single support wafer 101, and a groove is configured by two adjacent monocrystal layers 102 and the support wafer 101.

After forming the semiconductor crystal layer forming wafer 100 illustrated in FIG. 22, a filling layer 702 is formed, and a groove configured by two adjacent monocrystal layers 102 and the support wafer 101 is filled with the filling layer 702 as illustrated in FIG. 37. Examples of the filling layer 702 include an insulating layer that excels in step coverage (the property to fill the groove), for example, a silicon oxide layer that is formed by CVD by using TEOS (tetraethoxysilane) or TMOS (tetramethoxysilane) as the raw material gas, a SOG (spin-on glass), and the like. In the present example, the front surface of the monocrystal layer 102 is also covered with the filling layer 702.

As illustrated in FIG. 38, the filling layer 702 is polished by the polishing pad 103. Note that, as illustrated in FIG. 39, the filling layer 702 is polished such that the front surface of the monocrystal layer 102 becomes substantially flush with the front surface of the filling layer 702. In this manner, the semiconductor crystal layer forming wafer 700 is formed.

The semiconductor crystal layer forming wafer 700 is formed such that the front surface of the monocrystal layer 102 becomes substantially flush with the front surface of the filling layer 702. For this reason, when the semiconductor crystal layer 106 or the like is formed by using the semiconductor crystal layer forming wafer 700 in epitaxial growth, the gas flow in the epitaxial growth is not disturbed, and a uniform semiconductor crystal layer 106 can be formed.

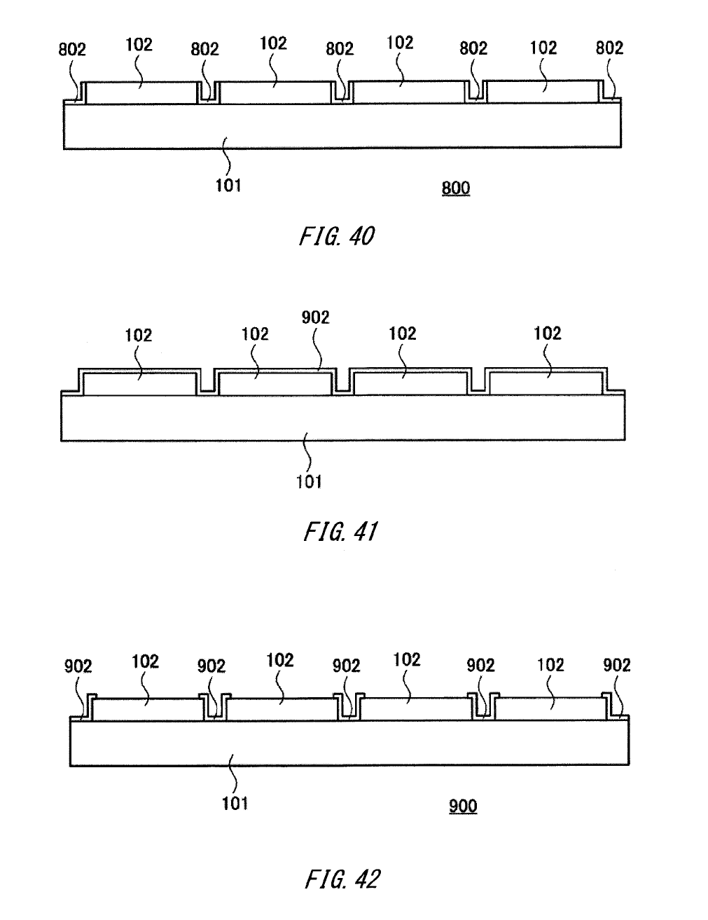

Note that in the above-mentioned embodiments, as illustrated in FIG. 40, a growth inhibition layer 802 to inhibit growth of the semiconductor crystal layer 106 may be formed at a portion where the monocrystal layer 102 is not formed, for example, at a groove between monocrystal layers 102. In the seventh embodiment, the growth inhibition layer 802 may be formed in place of the filling layer 702. The growth inhibition layer 802 enables formation of the semiconductor crystal layer 106 only at desired portions. Note that regions where the growth inhibition layer 802 may be formed are: the side surface of the monocrystal layer 102 formed on the support wafer 101; the front surface of a layer formed on the side surface (that is, an exposed surface of a layer that is formed on the side surface of the monocrystal layer 102 and extends in a direction parallel to the front surface of the support wafer 101); the front surface of the support wafer 101 in a non-formation region where the monocrystal layer 102 is not formed; and the front surface of a layer formed on the support wafer 101 in the non-formation region. The growth inhibition layer 802 may be formed before the formation of the monocrystal layer 102, or may be formed after the formation of the monocrystal layer 102.

In the above-mentioned embodiments, a buffer layer may be formed on the monocrystal layer 102 after forming the monocrystal layer 102 on the support wafer 101. By forming the buffer layer, the semiconductor crystal layer 106 can be formed readily in some cases. The buffer layer is a layer that has a lattice constant between those of the monocrystal layer 102 and the semiconductor crystal layer 106, for example.

In the above-mentioned embodiments, as illustrated in FIG. 41, after the monocrystal layer 102 is formed on the support wafer 101, a protection layer 902 to cover the monocrystal layer 102 is formed over the entire surface of the support wafer 101 surface on which the monocrystal layer 102 is formed. The, as illustrated in FIG. 42, a part of the protection layer 902 is removed such that the front surface of the monocrystal layer 102 or a layer formed on the monocrystal layer 102 (for example, the buffer layer) is exposed. The protection layer 902 may be formed to cover the entire surface of the support wafer 101 after forming a layer on the monocrystal layer 102 such as the buffer layer. A method that uses photolithography and etching, or polishing can be used to remove the protection layer 902.

When the monocrystal layer 102 before being bonded is formed by cleaving, attachment of fine particles can be prevented for example by removing burrs that occur at cleaved portions, removing powders that occur at the time of cleaving, cleaving in liquid, or protecting with a resist and the like before cleaving, or other measures. Because attachment of fine particles may lower the adhesiveness, it can be expected that these measures can enhance the adhesiveness.

### Eighth Example

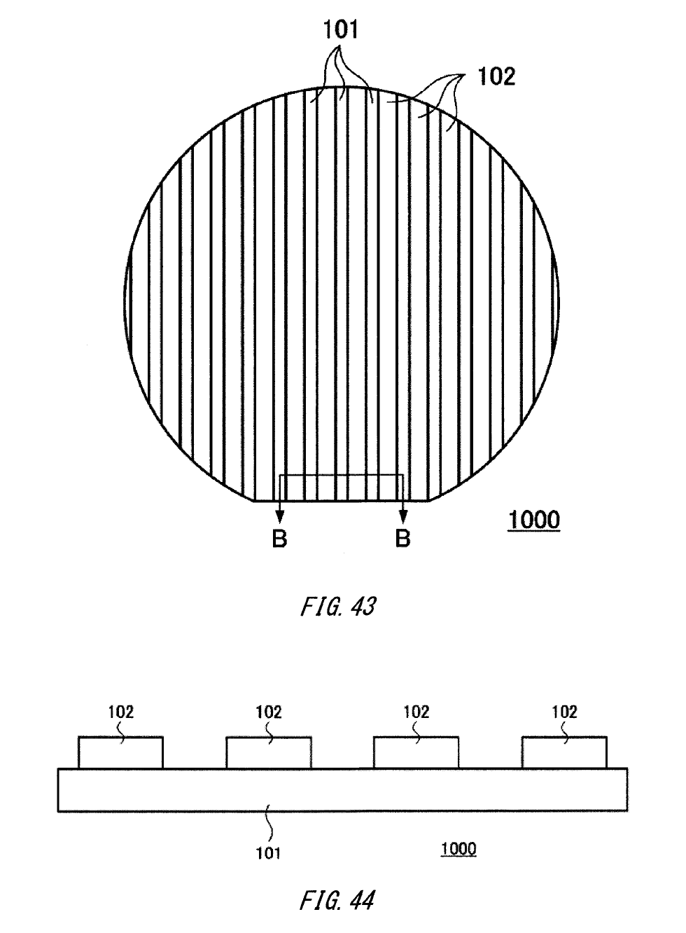

FIG. 43 is a plan view of a semiconductor crystal layer forming wafer 1000. FIG. 44 is a cross-sectional view of the semiconductor crystal layer forming wafer 1000. FIG. 44 illustrates a cross-section taken along the line B-B in FIG. 43. In the present eighth embodiment, a case where the planar shape of the monocrystal layers 102 on the support wafer 101 matches with the planar shape of the divided pieces 108 illustrated FIG. 7 and the like is described. That is, the respective monocrystal layers 102 in the present example are not divided into a plurality of the divided pieces 108.

The semiconductor crystal layer forming wafer 1000 in the present eighth embodiment has the support wafer 101 and the monocrystal layer 102. The support wafer 101 and the monocrystal layer 102 of the semiconductor crystal layer forming wafer 1000 are similar to those in the above-mentioned embodiments except for the matters that are explained below. However, the planar shape of the monocrystal layer 102 of the semiconductor crystal layer forming wafer 1000 is an LS pattern in which alternately disposed lines and grooves are spread, the lines having a width of 100 μm to 5 mm (monocrystal layer) and the grooves having a width of 1 μm to 20 mm. Examples of the length of the so-called lines include 5 cm to 50 cm. As illustrated in FIG. 43, the length of the lines may be the maximum length that is limited by the area (or the aperture diameter) of the support wafer 101 (the length between end faces of the support wafer 101).

The semiconductor crystal layer forming wafer 1000 can be produced as in the following manner. That is, on the entire surface of a growth wafer of a semiconductor crystal layer, a sacrificial layer and a crystal layer to be the monocrystal layer 102 are sequentially formed by using epitaxial growth for example. The crystal layer formed on the entire surface of the growth wafer is etched away, and a part of the sacrificial layer or the growth wafer is exposed. Thereby, the crystal layer is divided into a plurality of divided pieces. The divided pieces of the crystal layer formed on the growth wafer are transferred later onto the support wafer 101 to serve as the monocrystal layer 102.

A method for forming divided pieces of the crystal layer is as follows. By using a mask pattern that has the size and the groove width of the divided pieces, a resist mask is formed on a crystal layer by using a positive resist. The crystal layer is etched away by using the resist mask as a mask, and the divided pieces of the crystal layer are formed. The etching is preferably performed until reaching the growth wafer. That is, the etching preferably penetrates the sacrificial layer, and exposes the growth wafer.

The adhesiveness is enhanced by activating the front surfaces of the growth wafer on which the divided pieces of the crystal layer are formed, and the transfer target support wafer 101 by using ion beam. Thereafter, the front surfaces of the growth wafer having the divided pieces of the crystal layer, and the support wafer 101 are caused to face each other and bonded to each other to obtain a bonded wafer. At the time of bonding, the growth wafer and the support wafer 101 are attached under pressure as necessary. Due to this bonding, a cavity is formed by the inner wall of a groove formed between adjacent divided pieces and by the support wafer 101.

By introducing an etching agent into the cavity formed after the above-mentioned bonding, and etching the sacrificial layer of the growth wafer, the support wafer 101 and the growth wafer are separated from each other in a state that the divided piece of the crystal layer (the monocrystal layer 102) are left on the support wafer 101. In this manner, the semiconductor crystal layer forming wafer 1000 having the monocrystal layer 102 on the support wafer 101 can be produced.

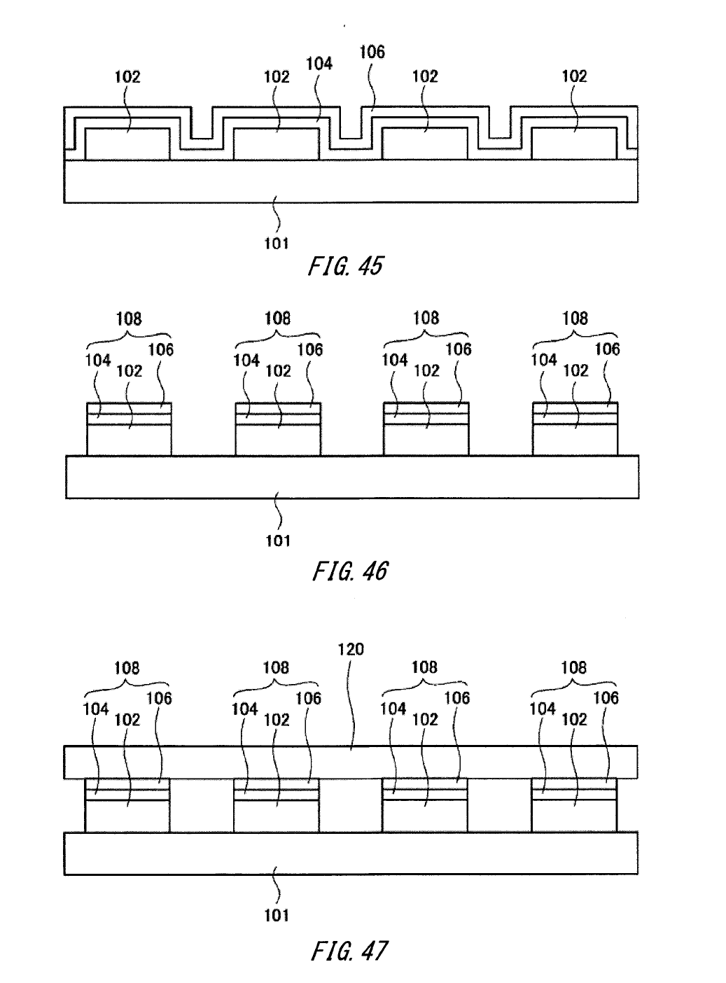

FIGS. 45 to 48 are cross-sectional views illustrating, in the order of steps, a method for producing a composite wafer by using the semiconductor crystal layer forming wafer 1000. As illustrated in FIG. 45, on the entire surface of the semiconductor crystal layer forming wafer 1000 formed in the above-mentioned manner, the sacrificial layer 104 and the semiconductor crystal layer 106 are sequentially formed by epitaxial growth for example.

In the semiconductor crystal layer forming wafer 1000 on which the sacrificial layer 104 and the semiconductor crystal layer 106 have been formed, the semiconductor crystal layer 106 is etched away such that a part of the sacrificial layer 104 is exposed. In the present example, as illustrated in FIG. 46, the semiconductor crystal layer 106 is etched away by using an LS pattern that is similar to the LS pattern of the monocrystal layer 102. Thereby, the semiconductor crystal layer 106 is divided into a plurality of divided pieces 108, and grooves are formed between adjacent divided pieces 108.

The divided pieces 108 can be formed in the following manner. A positive resist mask having an LS pattern with a line width and a groove width that are the same with those of the monocrystal layer 102 is formed on the semiconductor crystal layer 106 so as to match the pattern of the monocrystal layer 102. Next, the semiconductor crystal layer 106 and the sacrificial layer 104 are etched away by using the positive resist mask as a mask. The etching is preferably performed until reaching the support wafer 101.

The adhesiveness is enhanced by activating the front surfaces of the semiconductor crystal layer forming wafer 1000 having the semiconductor crystal layer 106, and the transfer target wafer 120 by using ion beam. Next, the front surface of the semiconductor crystal layer 106, and the front surface of the transfer target wafer 120 are caused to face and bonded to each other to obtain a bonded wafer as illustrated in FIG. 47. At the time of bonding, the front surface of the semiconductor crystal layer 106, and the front surface of the transfer target wafer 120 are attached under pressure as necessary. Due to this bonding, a cavity is formed by a groove formed between adjacent divided pieces 108, and the transfer target wafer 120.

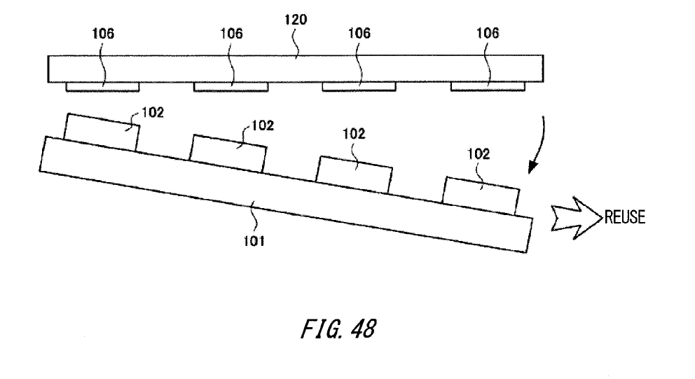

As illustrated in FIG. 48, the sacrificial layer 104 is etched away by introducing an etching agent into a cavity. By removing the sacrificial layer 104 by performing etching, the transfer target wafer 120 and the semiconductor crystal layer forming wafer 1000 can be separated from each other in a state that the semiconductor crystal layer 106 is left on the transfer target wafer 120. The etching of the sacrificial layer 104 can be performed by immersing the side surface of the bonded wafer in an etching solution (agent), introducing the etching solution into a cavity by using the capillary phenomenon, and allowing the sacrificial layer 104 to stand still. Thereby, the etching of the sacrificial layer 104 proceeds, the transfer target wafer 120 and the semiconductor crystal layer forming wafer 1000 are separated from each other, and a composite wafer having the semiconductor crystal layer 106 on the transfer target wafer 120 is obtained. Note that the semiconductor crystal layer forming wafer 1000 is reused.

In the above-mentioned fifth to eighth embodiments, the smoothing and activation in the third embodiment may be applied, and the intermediate layer 302 in the fourth embodiment may be applied. Also, the corners 402 illustrated in FIG. 26 may be applied.

In the above-mentioned embodiments, an electronic circuit constituted with a semiconductor device and the like may be formed on the transfer target wafer 120 or the second transfer target wafer 150. After forming an insulating layer on the entire front surface of a wafer on which the electronic circuit has been formed, the transfer target wafer 120 or the second transfer target wafer 150 may be flattened. The semiconductor crystal layer 106 may be bonded to a region that is different from the region of the transfer target wafer 120 or the second transfer target wafer 150 where the electronic circuit is formed, or the semiconductor crystal layer 106 may be bonded to overlap the region where the electronic circuit has been formed.

### First Example

A method for producing the semiconductor crystal layer forming wafer 1000 described in the eighth example is specifically described. A 4-inch GaAs wafer was used as a growth wafer of a semiconductor crystal layer to serve as the monocrystal layer 102 of the semiconductor crystal layer forming wafer 1000. A 4-inch Si wafer was used as the support wafer 101 of the semiconductor crystal layer forming wafer 1000, and a GaAs crystal layer was used as a semiconductor crystal layer to serve as the monocrystal layer 102.

On the entire surface of the 4-inch GaAs wafer which was the growth wafer, the AlAs crystal layer to serve as the sacrificial layer and the GaAs crystal layer to serve as the monocrystal layer 102 were sequentially formed by using epitaxial growth by low-pressure MOCVD

The thickness of the AlAs crystal layer and the GaAs crystal layer was 7 nm and 1.0 μm, respectively.

A positive resist film having a 300/200-μm LS pattern was formed on the GaAs crystal layer, and the AlAs crystal layer and the GaAs crystal layer were etched away by using the resist film as a mask until reaching the 4-inch GaAs wafer. Due to the etching, the GaAs crystal layer was divided into a plurality of divided pieces. A phosphoric acid-based etchant was used as the etching agent for the GaAs crystal layer.

The GaAs crystal layer front surface of the 4-inch GaAs wafer and the front surface of the 4-inch Si wafer which was the support wafer 101 were irradiated with argon ion beam in vacuo to activate the front surfaces. Thereafter, the front surface of the GaAs crystal layer was caused to face the front surface of the 4-inch Si wafer in vacuo, and the 4-inch GaAs wafer and the 4-inch Si wafer were bonded to each other. At the time of the bonding, a load of 100000 N (pressure: 12.3 MPa) was applied to attach both the wafers under pressure. The attachment under pressure was performed at normal temperature.

An etching solution was introduced into a cavity formed by a groove between adjacent divided pieces of the GaAs crystal layer, the AlAs crystal layer which was the sacrificial layer was removed by performing etching, and the 4-inch GaAs wafer and the 4-inch Si wafer were separated from each other in a state that the GaAs crystal layer was left on the 4-inch Si wafer. The etching of the AlAs crystal layer was performed by immersing the side surface of a bonded wafer in the etching solution at 23° C. whose HCl concentration was 10% by mass (10% hydrogen chloride solution), introducing the etching solution into the cavity by using the capillary phenomenon, and allowing the AlAs crystal layer to stand still. In this manner, a semiconductor crystal layer forming wafer having a 1.0-μm thick GaAs crystal layer with the 300/200-μm LS pattern on the 4-inch Si wafer was obtained.

### Second Example

By using the semiconductor crystal layer forming wafer 1000 obtained in the first example and by the method described in the eighth example, a composite wafer was produced. A 7-nm thick AlAs crystal layer was used as the sacrificial layer 104, and a 100-nm thick GaAs crystal layer was used as the semiconductor crystal layer 106. A 4-inch Si wafer was used as the transfer target wafer 120.

On the entire surface of the semiconductor crystal layer forming wafer 1000, a 7-nm thick AlAs crystal layer and a 100-nm thick GaAs crystal layer were sequentially formed by using epitaxial growth by low-pressure MOCVD. A positive resist film with the 300/200-μm LS pattern to match the 300/200-μm LS pattern of the GaAs crystal layer which was the monocrystal layer 102 was formed on the 100-nm thick GaAs crystal layer, and the GaAs crystal layer and the AlAs crystal layer were etched away by using the positive resist film as a mask until reaching the Si wafer which was the support wafer 101. Phosphoric acid-based etchant was used for etching of the GaAs crystal layer.

The front surface of the GaAs crystal layer which was the semiconductor crystal layer 106 and the front surface of the 4-inch Si wafer which was the transfer target wafer 120 were irradiated with argon ion beam in vacuo to activate the front surfaces. Thereafter, the front surface of the GaAs crystal layer was caused to face the front surface of the 4-inch Si wafer in vacuo, and the semiconductor crystal layer forming wafer 1000 and the 4-inch Si wafer were bonded to each other. At the time of the bonding, a load of 100000 N (pressure: 12.3 MPa) was applied to attach both the wafers under pressure. The attachment under pressure was performed at normal temperature.

An etching solution was introduced into a cavity formed by a groove between the semiconductor crystal layers 106 (the divided pieces 108), the AlAs crystal layer which was the sacrificial layer 104 was removed by performing etching, and the semiconductor crystal layer forming wafer 1000 and the 4-inch Si wafer were separated from each other in a state that the GaAs crystal layer was left on the 4-inch Si wafer. In this manner, a composite wafer having the 100-nm thick GaAs crystal layer with the 300/200 μm LS pattern on the 4-inch Si wafer which was the transfer target wafer 120 was obtained. By using the semiconductor crystal layer forming wafer obtained here as the growth wafer, and repeating the above-described steps on a plurality of the transfer target wafers 120, composite wafers having the 100-nm thick GaAs crystal layers with the 300/200 μm LS patterns on the 4-inch Si wafers were repeatedly obtained.

### Third Example

Except that a 12-inch Si wafer was used as the support wafer 101, a semiconductor crystal layer forming wafer was formed as in the first example. Also when the 12-inch Si wafer was used as the support wafer 101, a semiconductor crystal layer forming wafer having a 1.0-μm thick GaAs crystal layer with the 300/200-μm LS pattern on the 12-inch Si wafer was obtained as in the first example.

### Fourth Example

Except that the semiconductor crystal layer forming wafer obtained in the third example was used as the semiconductor crystal layer forming wafer 1000 and that a 12-inch Si wafer was used as the transfer target wafer 120, a composite wafer was formed as in the second example. However, the load applied at the time of bonding was 100000 N (pressure: 1.37 MPa). Also when the 12-inch Si wafer was used as the transfer target wafer 120, a composite wafer having a 100-nm thick GaAs crystal layer with the 300/200-μm LS pattern on the 12-inch Si wafer was obtained as in the second example.

### Fifth Example

Except that a 1-μm thick Ge crystal layer was used in place of a 100-nm thick GaAs crystal layer as the semiconductor crystal layer 106, a composite wafer was produced by a method similar to the method in the second example. Thereby, by using the semiconductor crystal layer forming wafer 1000 obtained in the first example and by a method that is similar to the method of the second example, a composite wafer having a 1-μm thick Ge crystal layer with the 300/200-μm LS pattern on the 4-inch Si wafer which was the transfer target wafer 120 was obtained.

By using the semiconductor crystal layer forming wafer obtained here as a growth wafer and by repeating the above-described steps on a plurality of the transfer target wafers 120, composite wafers having 1-μm thick Ge crystal layers with the 300/200-μm LS patterns on 4-inch Si wafers were repeatedly obtained.

### Sixth Example

A method for producing the semiconductor crystal layer forming wafer 1000 is specifically described. A 4-inch GaAs wafer was used as a growth wafer of a semiconductor crystal layer to serve as the monocrystal layer 102 of the semiconductor crystal layer forming wafer 1000. A 4-inch Si wafer was used as the support wafer 101 of the semiconductor crystal layer forming wafer 1000, and a GaAs crystal layer was used as a semiconductor crystal layer to serve as the monocrystal layer 102.

After protecting the front surface of the 4-inch GaAs wafer with a resist, the 4-inch GaAs wafer was cleaved into square plate-like shapes each with 2-cm sides, and four samples with planar shapes each having 2-cm sides were obtained. After removing the resist on the front surface by acetone, the GaAs wafer front surfaces each with 2-cm sides, and the front surface of the 4-inch Si wafer which was the support wafer 101 were irradiated with argon ion beam in vacuo to activate the front surfaces. Thereafter, the front surface of the GaAs crystal layer was caused to face the front surface of the 4-inch Si wafer in vacuo, and the four GaAs wafers each with 2-cm sides, and the 4-inch Si wafer were bonded to each other. At the time of the bonding, a load of 3000 N (pressure: 1.88 MPa) was applied to attach both the wafers under pressure. The attachment under pressure was performed at normal temperature. A semiconductor crystal layer forming wafer having four GaAs wafers each with 2-cm sides on the 4-inch Si wafer was obtained. Furthermore, the GaAs wafer front surface of this semiconductor crystal layer forming wafer was subjected to CMP processing.

### Seventh Example

A composite wafer was produced by a method similar to the method of the second example by using the semiconductor crystal layer forming wafer 1000 obtained in the sixth example. Thereby a composite wafer having the 100-nm thick GaAs crystal layer with the 300/200-μm LS pattern on the 4-inch Si wafer which was the transfer target wafer 120 was obtained. By using the semiconductor crystal layer forming wafer obtained here as the growth wafer, and repeating the above-described steps on a plurality of the transfer target wafers 120, composite wafers having the 100-nm thick GaAs crystal layers with the 300/200 μm LS patterns on the 4-inch Si wafers were repeatedly obtained.

When it is described in the present specification that a second element is located “on” a first element such as a layer or a wafer, such a description indicates a case where the second element is disposed directly on the first element, and also a case where the second element is disposed indirectly on the first element with another element being interposed between the second element and the first element. When the second element is formed “on” the first element also, similarly, the second element may be formed directly or indirectly on the first element. Also, terms like “on” or “under” that indicate directions indicate relative directions in a semiconductor wafer, a composite wafer, and a device, and may not indicate absolute directions relative to an external reference surface such as the ground.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A method for producing a composite wafer that has a semiconductor crystal layer on a transfer target wafer by using a semiconductor crystal layer forming wafer, the semiconductor crystal layer forming wafer having a support wafer and a monocrystal layer supported, directly or via an intermediate layer, on the front surface or the back surface of the support wafer, the method comprising:
(a) forming, on the monocrystal layer of the semiconductor crystal layer forming wafer, a sacrificial layer and the semiconductor crystal layer in the order of the monocrystal layer, the sacrificial layer, and the semiconductor crystal layer;
(b) causing a first front surface that is the front surface of a layer formed on the semiconductor crystal layer forming wafer to face a second front surface that is the front surface of the transfer target wafer or of a layer formed on the transfer target wafer and is to contact the first front surface, and bonding the semiconductor crystal layer forming wafer and the transfer target wafer; and
(c) etching the sacrificial layer, and separating the semiconductor crystal layer forming wafer from the transfer target wafer in a state that the semiconductor crystal layer is left on the transfer target wafer, wherein
the (a) to the (c) are repeated by using the semiconductor crystal layer forming wafer separated in the (c).

2. The method for producing a composite wafer according to claim 1, the method further comprising, before the (a), smoothing the front surface of the monocrystal layer of the semiconductor crystal layer forming wafer.

3. The method for producing a composite wafer according to claim 1, the method further comprising, after the (a) and before the (b), etching the semiconductor crystal layer so as to expose a part of the sacrificial layer, and dividing the semiconductor crystal layer into a plurality of divided pieces.

4. The method for producing a composite wafer according to claim 1, the method further comprising, after the (a) and before the (b), activating one or more front surfaces selected from the first front surface and the second front surface.

5. The method for producing a composite wafer according to claim 1, the method further comprising, after the (a) and before the (b), forming an insulating layer on the semiconductor crystal layer.

6. The method for producing a composite wafer according to claim 1, the method further comprising, before the (b), forming an insulating layer on the front surface of the transfer target wafer or of a layer formed on the transfer target wafer, the front surface being positioned on the semiconductor crystal layer forming wafer side.

7. The method for producing a composite wafer according to claim 1, wherein the transfer target wafer has a circular shape with a diameter of 200 mm or has any planar shape having an area larger than the circular shape.

8. The method for producing a composite wafer according to claim 1, the method further comprising:
before the (b), forming an adhesive layer on the front surface of the transfer target wafer or of a layer formed on the transfer target wafer, the front surface being positioned on the semiconductor crystal layer forming wafer side;
after the (c), causing a third front surface that is the front surface of the semiconductor crystal layer on the transfer target wafer or the front surface of a layer formed on the semiconductor crystal layer to face a fourth front surface that is the front surface of a second transfer target wafer or of a layer formed on the second transfer target wafer, and is to contact the third front surface, and bonding the transfer target wafer and the second transfer target wafer; and
removing the adhesive layer of the transfer target wafer, and separating the transfer target wafer and the second transfer target wafer in a state that the semiconductor crystal layer is left on the second transfer target wafer.

9. A method for producing a semiconductor crystal layer forming wafer to be used in the method for producing a composite wafer according to claim 1, the method for producing a semiconductor crystal layer forming wafer comprising:
smoothing one or more front surfaces selected from a fifth front surface of the support wafer that is to contact the monocrystal layer and a sixth front surface of the monocrystal layer that is to contact the support wafer;
activating one or more front surfaces selected from the fifth front surface and the sixth front surface; and
causing the fifth front surface to face the sixth front surface, and bonding the support wafer and the monocrystal layer to form the monocrystal layer on the support wafer.

10. A method for producing a semiconductor crystal layer forming wafer to be used in the method for producing a composite wafer according to claim 1, the method for producing a semiconductor crystal layer forming wafer comprising:
forming a heat resistant intermediate layer on one or more front surfaces selected from the front surface positioned on the monocrystal layer side of the support wafer and the front surface positioned on the support wafer side of the monocrystal layer;
causing a seventh front surface that is the front surface of the support wafer or of the intermediate layer formed on the support wafer to face an eighth surface that is the front surface of the monocrystal layer or of the intermediate layer formed on the monocrystal layer, and is to contact the seventh front surface, and bonding the support wafer and the monocrystal layer to form the monocrystal layer on the support wafer.

11. The method for producing a semiconductor crystal layer forming wafer according to claim 10, the method further comprising, after forming the intermediate layer and before the bonding, activating one or more front surfaces selected from the seventh front surface and the eighth surface.

12. The method for producing a semiconductor crystal layer forming wafer according to claim 11, the method further comprising, after forming the intermediate layer, and before the activation, smoothing one or more front surfaces selected from the seventh front surface and the eighth surface.

13. The method for producing a semiconductor crystal layer forming wafer according to claim 9, wherein in the bonding, the support wafer and the monocrystal layer are heated to 100 to 200° C.

14. The method for producing a semiconductor crystal layer forming wafer according to claim 9, wherein the support wafer has a circular shape with a diameter of 200 mm or has any planar shape having an area larger than the circular shape.

15. The method for producing a semiconductor crystal layer forming wafer according to claim 9, wherein
the planar shape of the monocrystal layer bonded to the support wafer has a corner,
the method further comprising after bonding the support wafer and the monocrystal layer, performing processing to round the corner of the monocrystal layer.

16. A method for producing a semiconductor crystal layer forming wafer to be used in the method for producing a composite wafer according to claim 1, the method for producing a semiconductor crystal layer forming wafer comprising:
forming a monocrystal growth layer on the support wafer by using epitaxial growth; and
forming the monocrystal layer on the support wafer by patterning the monocrystal growth layer.

17. The method for producing a semiconductor crystal layer forming wafer according to claim 9, the method further comprising, before forming the monocrystal layer on the support wafer, forming a concave portion on the support wafer, wherein
in forming the monocrystal layer, the monocrystal layer is formed at the concave portion.

18. The method for producing a semiconductor crystal layer forming wafer according to claim 17, the method further comprising polishing the monocrystal layer or the support wafer such that the front surface of the monocrystal layer formed at the concave portion becomes substantially flush with the front surface of the support wafer.

19. The method for producing a semiconductor crystal layer forming wafer according to claim 9, the method further comprising, before forming the monocrystal layer on the support wafer, performing surface processing on a region of the support wafer where the monocrystal layer is formed or is not formed, wherein
in forming the monocrystal layer, the monocrystal layer is formed in the region on which the surface processing has been performed or has not been performed, the monocrystal layer being formed by being caused to self-align with the region.

20. The method for producing a semiconductor crystal layer forming wafer according to claim 9, the method further comprising forming a filling layer to fill a groove, a plurality of the monocrystal layers being formed within a surface of the single support wafer, the groove being constituted with two adjacent ones of the monocrystal layers, and the support wafer.

21. The method for producing a semiconductor crystal layer forming wafer according to claim 20, the method further comprising polishing the monocrystal layer or the filling layer such that the front surface of the monocrystal layer becomes substantially flush with the front surface of the filling layer.
